(19) United States
(12) Patent Application Publication
(10) Pub. No.: US 2013/0180843 A1
(43) Pub. Date: Jul. 18, 2013

(54) DIRECTED MULTI-DEFLECTED ION BEAM MILLING OF A WORK PIECE AND DETERMINING AND CONTROLLING EXTENT THEREOF

(71) Applicants: Dimitri BOGUSLAVSKY, Haifa (IL); Valentin CHEREPIN, Kiev (UA); Colin SMITH, Moshav Amikam (IL)

(72) Inventors: Dimitri BOGUSLAVSKY, Haifa (IL); Valentin CHEREPIN, Kiev (UA); Colin SMITH, Moshav Amikam (IL)

(73) Assignee: CAMTEK LTD., Migdal Haemek (IL)

(21) Appl. No.: 13/550,628

(22) Filed: Jul. 17, 2012

Related U.S. Application Data
(63) Continuation of application No. 11/661,201, filed on Oct. 24, 2007.
(60) Provisional application No. 60/603,544, filed on Aug. 24, 2004.

(51) Int. Cl. H01J 37/305

(52) U.S. Cl. CPC H01J 37/3056
USPC 204/192.33; 204/192.34; 204/298.36; 204/298.32

(57) ABSTRACT

Method, device, and system, for directed multi-deflected ion beam milling of a work piece, and, determining and controlling extent thereof. Providing an ion beam; and directing and at least twice deflecting the provided ion beam, for forming a directed multi-deflected ion beam, wherein the directed multi-deflected ion beam is directed towards, incident and impinges upon, and mills, a surface of the work piece. Device includes an ion beam source assembly; and an ion beam directing and multi-deflecting assembly, for directing and at least twice deflecting the provided ion beam, for forming a directed multi-deflected ion beam, wherein the directed multi-deflected ion beam is directed towards, incident and impinges upon, and mills, a surface of the work piece.

### RELATED APPLICATION

This application is a continuation application and claims the priority of U.S. patent application Ser. No. 11/661,201 filing date Oct. 24, 2007 which claims the benefit of PCT patent application serial number PCT/IL05/00913 international filing date Aug. 24, 2005, all patent applications are incorporated herein by reference.

### FIELD AND BACKGROUND OF THE INVENTION

The present invention relates to ion beam milling of a work piece, and more particularly, to a method, device, and system, for directed multi-deflected ion beam milling of a work piece, and, determining and controlling extent thereof. The present invention is generally applicable in a wide variety of different fields, such as semiconductor manufacturing, micro-analytical testing, materials science, metrology, lithography, micro-machining, and nanofabrication. The present invention is generally implementable in a wide variety of different applications of ion beam milling of a wide variety of different types of work pieces. The present invention is particularly implementable in a variety of different applications of preparing or/and analyzing a wide variety of different types of work pieces, particularly in the form of samples or materials, such as those derived from semiconductor wafers or chips, that are widely used in the above indicated exemplary fields. Ion beam milling (etching) of a work piece (sample), directing an ion beam, deflecting an ion beam, and rotating an ion beam, theory, principles, and practices thereof, and, related and associated applications and subjects thereof, are well known and taught about in the prior art, and currently widely practiced. For the purpose of establishing the scope, meaning, and field(s) of application, of the present invention, following are selected definitions and exemplary usages of terminology used for disclosing the present invention.

### Work Piece

Herein, in a non-limiting manner, work piece generally refers to any of a wide variety of different types of materials, such as semiconductor materials, ceramic materials, pure metallic materials, metal alloy materials, polymeric materials, composite materials thereof, or materials derived therefrom.

For example, for a work piece being a semiconductor type of material, the work piece is typically in the form of a sample derived from a single die (of a wafer), a wafer segment, or a whole wafer. Ordinarily, such a work piece (sample) is pre-prepared using a micro-analytical sample preparation technique, for example, such as that disclosed in U.S. Provisional Patent Application No. 60/649,080, filed Feb. 3, 2005, entitled: “Sample Preparation For Micro-analysis”, assigned to the present applicant/assignee. Pre-preparing the work piece (sample) using a micro-analytical sample preparation technique is based on ‘sectioning’ or ‘segmenting’ at least a part of the work piece (sample) precursor, via reducing or thinning at least one dimension (length, width, or/and thickness, depth or height) of the size of the work piece (sample) precursor, by using one or more types of a cutting, cleaving, slicing, or/and polishing, procedure, thereby producing a prepared work piece (sample) ready for subjection to another process, for example, ion beam milling. Such a prepared work piece (sample) has at least one dimension (length, width, or/and thickness, depth or height) in a range of between about 10 microns and about 50 microns, and another dimension in a range of between about 2 millimeters and about 3 millimeters.

### Ion Beam Milling of a Work Piece

Ion beam milling of a work piece generally refers to impinging an ion beam onto a surface of the work piece, whereby interaction of the ion beam with the surface leads to removal of material from the surface, and therefore, from the work piece. In various fields, focused ion beam (FIB) milling and broad ion beam (BIB) milling are well known, taught about, and used, techniques of ion beam milling of a work piece. In general, focused ion beam (FIB) milling refers to a highly energetic, concentrated, and well focused, ion beam, originating from a liquid metal source, such as liquid gallium, which is incident and impinges upon, and mills, a surface of a work piece, whereby interaction of the focused ion beam with the surface leads to removal of material from the surface of the work piece. In general, broad ion beam (BIB) milling refers to a less energetic and less focused, broad ion beam, originating from an inert gas source, such as argon or xenon, which is incident and impinges upon, and mills, the surface of a work piece, whereby interaction of the broad ion beam with the surface leads to removal of material from the surface of the work piece.

In general, ion beam milling involving an ion beam incident and impinging upon a surface of a work piece, whereby interaction of the ion beam with the surface leads to a ‘selective’ type of removal of material from the surface, can be considered ion beam ‘etching’. In the scope and context of the present invention, herein, ion beam milling generally refers to an ion beam incident and impinging upon a surface of a work piece, whereby interaction of the ion beam with the surface leads to a non-selective, or a selective, type of removal of material from the surface of the work piece.

### Directing an Ion Beam:

In the phrase ‘directing an ion beam’, the term ‘directing’ is generally equivalent to the synonymous terms guiding, regulating, controlling, and associated different grammatical forms thereof. Thus, directing an ion beam is generally equivalent to guiding, regulating, or controlling, an ion beam. In general, a directed, guided, regulated, or controlled, ion beam is directed, guided, regulated, or controlled, in or along a direction, axis, path, or trajectory, toward an object, entity, or target, herein, generally referred to as a work piece. Such directing, guiding, regulating, or controlling, of an ion beam may be accomplished by a wide variety of different types of means which are well known, taught about, and used, in the prior art of ion beam and related technologies.

### Deflecting an Ion Beam:

In the phrase ‘deflecting an ion beam’, the term ‘deflecting’ is generally equivalent to the synonymous terms swerving, turning aside, bending, deviating, or alternatively, to the synonymous phrases to cause to swerve, to cause to turn aside, to cause to bend, to cause to deviate, respectively, and associated different grammatical forms thereof. Thus, deflecting an ion beam is generally equivalent to swerving, turning aside, bending, or deviating, an ion beam, or alternatively, causing an ion beam to swerve, turn aside, bend, or deviate, respectively, or alternatively, causing an ion beam to be swerved, turned aside, bent, or deviated, respectively, resulting in swerving, turning aside, bending, or deviating, respectively, of the ion beam. In general, an ion beam is deflected, caused to swerve, turned aside, bent, or deviated, from a first direction, path, axis, or trajectory, to a second direction, path, axis, or trajectory, respectively. Such deflecting, causing to swerve, turning aside, bending, or deviating, of an ion beam may be accomplished by a wide variety of different types of means which are well known, taught about, and used, in the prior art of ion beam and related technologies.

### Rotating an Ion Beam:

In the phrase ‘rotating an ion beam’, the term ‘rotating’ is generally equivalent to the synonymous terms turning or spinning on, around, or relative to, an axis, or alternatively, to the synonymous phrases to cause to turn, or to cause to spin, respectively, on, around, or relative to, an axis, and associated different grammatical forms thereof. Thus, rotating an ion beam is generally equivalent to turning or spinning, an ion beam, on, around, or relative to, an axis, or alternatively, causing an ion beam to turn or spin, respectively, on, around, or relative to, an axis, or alternatively, causing an ion beam to be turned or spun, respectively, on, around, or relative to, an axis, resulting in turning or spinning, respectively, of the ion beam, on, around, or relative to, an axis.

In general, an ion beam is rotated (rotates), turned (turns), or spun (spins), on, around, or relative to, an axis, where the axis is either an axis of the ion beam, or an axis of an element or component which ordinarily shares the same spatial and temporal domains as the ion beam. Moreover, such rotating, turning, or spinning, of an ion beam on, around, or relative to, an axis, corresponds to angularly displacing the ion beam on, around, or relative to, the axis, where the axis is either an axis of the ion beam, or an axis of an element or component which ordinarily shares the same spatial and temporal domains as the ion beam. Such rotating, turning, or spinning, of an ion beam, on, around, or relative to, an axis, may be accomplished by techniques known, taught about, and used, in the prior art of ion beam and related technologies. For example, by rotating, turning, or spinning, an ion beam source, such as a device or assembly which generates or produces the ion beam, on, around, or relative to, an axis, however, in such cases, it is significant to point out that the ion beam is stationary (static or fixed) relative to the ion beam source.

FIG. 1 is a schematic diagram illustrating a perspective view of an exemplary work piece, being a typical pre-prepared sample of a portion of a semiconductor wafer or chip having a surface (with a masking element), and selected features and parameters thereof, held by a sample holder element, where the sample is to be subjected to ion beam milling, for example, by implementing the present invention, for example, as part of preparing the sample for micro-analysis, or/and as part of analyzing the sample.

Implementation of prior art techniques of ion beam milling of a work piece is limited by an inability to simultaneously and automatically achieve the following four characteristics or aspects relating to preparing or/and analyzing a work piece: (1) thickness or thinness of a section of the work piece, (2) ability to locate a site specific target in a milled work piece, (3) depth of a site specific target within the work piece, and (4) quality of the milled surfaces of the work piece, including control of selectivity of the milled surfaces.

There is thus a need for, and it would be highly advantageous to have a method, device, and system, for directed multi-deflected ion beam milling of a work piece, and, determining and controlling extent thereof. There is need for such an invention which is generally applicable in a wide variety of different fields, such as semiconductor manufacturing, micro-analytical testing, materials science, metrology, lithography, micro-machining, and nanofabrication. Moreover, there is need for such an invention which is generally implementable in a wide variety of different applications of ion beam milling of a wide variety of different types of work pieces. Additionally, there is need for such an invention which is particularly implementable in a variety of different applications of preparing or/and analyzing a wide variety of different types of work pieces, particularly in the form of samples or materials, such as those derived from semiconductor wafers or chips, that are widely used in the above indicated exemplary fields.

### SUMMARY OF THE INVENTION

The present invention relates to ion beam milling of a surface, and more particularly, to a method, device, and system, for directed multi-deflected ion beam milling of a work piece, and, determining and controlling extent thereof. The present invention is generally applicable in a wide variety of different fields, such as semiconductor manufacturing, micro-analytical testing, materials science, metrology, lithography, micro-machining, and nanofabrication. The present invention is generally implementable in a wide variety of different applications of ion beam milling of a wide variety of different types of work pieces. The present invention is particularly implementable in a variety of different applications of preparing or/and analyzing a wide variety of different types of work pieces, particularly in the form of samples or materials, such as those derived from semiconductor wafers or chips, that are widely used in the above indicated exemplary fields.

Thus, according to the present invention, there is provided a method for directed multi-deflected ion beam milling of a work piece, comprising: providing an ion beam; and directing and at least twice deflecting the provided ion beam, for forming a directed multi-deflected ion beam, wherein the directed multi-deflected ion beam is directed towards, incident and impinges upon, and mills, a surface of the work piece.

According to another aspect of the present invention, there is provided a method for directed multi-deflecting a provided ion beam, comprising: directing and at least twice deflecting the provided ion beam, for forming a directed multi-deflected ion beam, by deflecting and directing the provided ion beam, for forming a directed once deflected ion beam, and, deflecting and directing the directed once deflected ion beam, for forming a directed twice deflected ion beam being a type of the directed multi-deflected ion beam.

According to another aspect of the present invention, there is provided a device for directed multi-deflected ion beam milling of a work piece, comprising: an ion beam source assembly, for providing an ion beam; and an ion beam directing and multi-deflecting assembly, for directing and at least twice deflecting the provided ion beam, for forming a directed multi-deflected ion beam, wherein the directed multi-deflected ion beam is directed towards, incident and impinges upon, and mills, a surface of the work piece.

According to another aspect of the present invention, there is provided a device for directed multi-deflecting a provided ion beam, comprising: an ion beam directing and multi-deflecting assembly, for directing and at least twice deflecting the provided ion beam, for forming a directed multi-deflected ion beam, wherein the ion beam directing and multi-deflecting assembly includes an ion beam first deflecting assembly, for deflecting and directing the provided ion beam, for forming a directed once deflected ion beam, and an ion beam second deflecting assembly, for deflecting and directing the directed once deflected ion beam, for forming a directed twice deflected ion beam being a type of the directed multi-deflected ion beam.

According to another aspect of the present invention, there is provided a system for directed multi-deflected ion beam milling of a work piece, comprising: an ion beam unit, wherein the ion beam unit includes an ion beam source assembly, for providing an ion beam, and an ion beam directing and multi-deflecting assembly, for directing and at least twice deflecting the provided ion beam, for forming a directed multi-deflected ion beam, wherein the directed multi-deflected ion beam is directed towards, incident and impinges upon, and mills, a surface of the work piece; and a vacuum unit, operatively connected to the ion beam unit, for providing and maintaining a vacuum environment for the ion beam unit and the work piece, wherein the vacuum unit includes the work piece.

According to further characteristics in preferred embodiments of the invention described below, the system further includes electronics and process control utilities, operatively connected to the ion beam unit and to the vacuum unit, for providing electronics to, and enabling process control of, the ion beam unit and the vacuum unit.

According to further characteristics in preferred embodiments of the invention described below, the system further includes at least one additional unit selected from the group consisting of: a work piece imaging and milling detection unit, a work piece manipulating and positioning unit, an anti-vibration unit, a component imaging unit, and at least one work piece analytical unit, wherein each additional unit is operatively connected to the vacuum unit.

According to another aspect of the present invention, there is provided a system for directed multi-deflecting a provided ion beam, comprising: an ion beam unit, wherein the ion beam unit includes an ion beam directing and multi-deflecting assembly, for directing and at least twice deflecting the provided ion beam, for forming a directed multi-deflected ion beam, the ion beam directing and multi-deflecting assembly includes an ion beam first deflecting assembly, for deflecting and directing the provided ion beam, for forming a directed once deflected ion beam, and an ion beam second deflecting assembly, for deflecting and directing the directed once deflected ion beam, for forming a directed twice deflected ion beam being a type of the multi-deflected ion beam; and a vacuum unit, operatively connected to the ion beam unit, for providing and maintaining a vacuum environment for the ion beam unit.

According to further characteristics in preferred embodiments of the invention described below, the system further includes electronics and process control utilities, operatively connected to the ion beam unit and to the vacuum unit, for providing electronics to, and enabling process control of, the ion beam unit and the vacuum unit.

According to further characteristics in preferred embodiments of the invention described below, the system further includes at least one additional unit selected from the group consisting of: a work piece imaging and milling detection unit, a work piece manipulating and positioning unit, an anti-vibration unit, a component imaging unit, and at least one work piece analytical unit, wherein each additional unit is operatively connected to the vacuum unit.

According to another aspect of the present invention, there is provided a method for determining and controlling extent of ion beam milling of a work piece, comprising: providing a set of pre-determined values of at least one parameter of the work piece selected from the group consisting of: thickness of the work piece, depth of a target within the work piece, and topography of at least one surface of the work piece; performing directed multi-deflected ion beam milling of the work piece using a method for the directed multi-deflected ion beam milling of a work piece, including the following main steps, and, components and functionalities thereof: providing an ion beam; and directing and at least twice deflecting the provided ion beam, for forming a directed multi-deflected ion beam, wherein the directed multi-deflected ion beam is directed towards, incident and impinges upon, and mills, a surface of the work piece; real time measuring in-situ the at least one parameter of the work piece, for forming a set of measured values of the at least one parameter; comparing the set of the measured values to the provided set of the pre-determined values, for forming a set of value differences associated with the comparing; feeding back the set of the value differences for continuing the performing directed multi-deflected ion beam milling of the work piece, until the value differences are within a pre-determined range.

According to further characteristics in preferred embodiments of the invention described below, the degree of selectivity of the at least one surface of the work piece corresponds to the topography as being one of the pre-determined parameters of the work piece.

The present invention is implemented by performing procedures, steps, and sub-steps, in a manner selected from the group consisting of manually, semi-automatically, fully automatically, and a combination thereof, involving use and operation of system units, system sub-units, devices, assemblies, sub-assemblies, mechanisms, structures, components, elements, and, peripheral equipment, utilities, accessories, and materials, in a manner selected from the group consisting of manually, semi-automatically, fully automatically, and a combination thereof. Moreover, according to actual procedures, steps, sub-steps, system units, system sub-units, devices, assemblies, sub-assemblies, mechanisms, structures, components, elements, and, peripheral equipment, utilities, accessories, and materials, used for implementing a particular embodiment of the disclosed invention, the procedures, steps, and sub-steps, are performed by using hardware, software, or/and an integrated combination thereof, and the system units, system sub-units, devices, assemblies, sub-assemblies, mechanisms, structures, components, elements, and, peripheral equipment, utilities, accessories, and materials, operate by using hardware, software, or/and an integrated combination thereof.

In particular, software used for implementing the present invention includes operatively connected and functioning written or printed data, in the form of software programs, software routines, software sub-routines, software symbolic languages, software code, software instructions or protocols, software algorithms, or/and a combination thereof. Hardware used for implementing the present invention includes operatively connected and functioning electrical, electronic, magnetic, electromagnetic, electromechanical, and optical, system units, system sub-units, devices, assemblies, sub-assemblies, mechanisms, structures, components, elements, and, peripheral equipment, utilities, accessories, and materials, which may include one or more computer chips, integrated circuits, electronic circuits, electronic sub-circuits, hard-wired electrical circuits, or/and combinations thereof, involving digital or/and analog operations. Accordingly, the present invention is implemented by using an integrated combination of the just described software and hardware.

### BRIEF DESCRIPTION OF THE DRAWINGS

The present invention is herein described, by way of example only, with reference to the accompanying drawings. With specific reference now to the drawings in detail, it is stressed that the particulars shown are by way of example and for purposes of illustrative description of the preferred embodiments of the present invention only, and are presented in the cause of providing what is believed to be the most useful and readily understood description of the principles and conceptual aspects of the present invention. In this regard, no attempt is made to show structural details of the present invention in more detail than is necessary for a fundamental understanding of the invention, the description taken with the drawings making apparent to those skilled in the art how the several forms of the invention may be embodied in practice. In the drawings:

FIG. 1 is a schematic diagram illustrating a perspective view of an exemplary work piece, being a typical pre-prepared sample of a portion of a semiconductor wafer or chip having a surface (with a masking element), and selected features and parameters thereof, held by a sample holder element, where the sample is to be subjected to ion beam milling, for example, by implementing the present invention, for example, as part of preparing the sample for micro-analysis, or/and as part of analyzing the sample;

FIG. 2 is a schematic diagram illustrating a side view of an exemplary preferred embodiment of directed multi-deflected ion beam milling of a work piece, and, determining and controlling extent thereof, particularly showing the ion beam unit in relation to the work piece imaging and milling detection unit and the vacuum chamber assembly of the vacuum unit, and all these in relation to the work piece and a surface thereof, in accordance with the present invention;

FIG. 3 is a schematic diagram illustrating a side view of a more detailed version of the exemplary preferred embodiment illustrated in FIG. 2, particularly showing an exemplary specific preferred embodiment of the device, being the ion beam unit, including the ion beam directing and multi-deflecting assembly, for twice deflecting an ion beam, and showing an exemplary specific preferred embodiment of the work piece imaging and milling detection unit, in accordance with the present invention;

FIG. 4 is a schematic diagram illustrating a side view of the directed multi-deflected ion beam milling of a work piece, and, determining and controlling extent thereof, illustrated in FIGS. 2 and 3, particularly showing a cross-sectional side view of a more detailed component level version of the device, being the ion beam unit, including the ion beam directing and multi-deflecting assembly, structured and functional for twice deflecting an ion beam, in accordance with the present invention;

FIG. 5 is a schematic diagram illustrating a perspective view of the directed multi-deflected ion beam milling of a work piece, illustrated in FIGS. 2, 3, and 4, particularly showing an exemplary specific preferred embodiment of each of the ion beam first deflecting assembly and the ion beam second deflecting assembly, included in the ion beam directing and multi-deflecting assembly of the ion beam unit, structured and functional for twice deflecting an ion beam, in accordance with the present invention;

FIGS. 6a-6e are schematic diagrams together illustrating a perspective view of a rotational (angular) sequence of an ion beam directed and multi-deflected, relative to an arbitrarily assigned longitudinal axis coaxial with the work piece, by the first ion beam deflecting assembly and the second ion beam deflecting assembly, corresponding to a directed twice deflected ion beam type of directed multi-deflected ion beam which rotates in a range of between 0 degrees and 360 degrees around the longitudinal axis, and is directed towards, incident and impinges upon, and mills, a surface of the work piece, in accordance with the present invention;

FIG. 7a is a schematic diagram illustrating a perspective close-up view of a directed multi-deflected (twice or thrice deflected) ion beam directed towards, incident and impinging upon, and milling, a surface of a first type of an exemplary work piece (a generally shaped rectangular slab), particularly showing relative geometries and dimensions of the ion beam, the surface, and the work piece, in accordance with the present invention;

FIG. 7b is a schematic diagram illustrating a perspective close-up view of a directed multi-deflected (twice or thrice deflected) ion beam directed towards, incident and impinging upon, and milling, a surface of a second type of an exemplary work piece (a typical sample of a portion of a semiconductor wafer or chip wherein the surface (with a mask) is held by a sample holder element, for example, similar to that illustrated in FIG. 1), particularly showing relative geometries and dimensions of the ion beam, the surface, and the work piece, in accordance with the present invention;

FIG. 8 is a schematic diagram illustrating a side view of a more detailed version of the exemplary preferred embodiment illustrated in FIG. 2, particularly showing an exemplary specific preferred embodiment of the ion beam unit, including the ion beam directing and multi-deflecting assembly, for thrice deflecting an ion beam, and an exemplary specific preferred embodiment of the work piece imaging and milling detection unit, in accordance with the present invention;

FIG. 9 is a schematic diagram illustrating a side view of the directed multi-deflected ion beam milling of a work piece, and, determining and controlling extent thereof, illustrated in FIGS. 2 and 8, particularly showing a cross-sectional side view of a more detailed component level version of the ion beam unit, including the ion beam directing and multi-deflecting assembly, structured and functional for twice deflecting an ion beam, in accordance with the present invention;

FIG. 10 is a schematic diagram illustrating a perspective view of the directed multi-deflected ion beam milling of a work piece, illustrated in FIGS. 2, 8, and 9, particularly showing an exemplary specific preferred embodiment of each of the ion beam first deflecting assembly, the ion beam second deflecting assembly, and the ion beam third deflecting assembly, included in the ion beam directing and multi-deflecting assembly of the ion beam unit, structured and functional for thrice deflecting an ion beam, in accordance with the present invention;

FIG. 11 is a block diagram illustrating an exemplary preferred embodiment of the system for directed multi-deflected ion beam milling of a work piece, including the ion beam unit and a vacuum unit, and various possible specific exemplary preferred embodiments thereof, by further including at least one additional unit selected from the group consisting of: a work piece imaging and milling detection unit, a work piece manipulating and positioning unit, an anti-vibration unit, a component imaging unit, and a work piece analytical unit, in accordance with the present invention;

FIG. 12 is an (isometric) schematic diagram illustrating a perspective view of the system, and additional units thereof, for directed multi-deflected ion beam milling of a work piece, illustrated in FIG. 11, in accordance with the present invention;

FIG. 13 is an (isometric) schematic diagram illustrating a top view of the system illustrated in FIGS. 11 and 12, in accordance with the present invention;

FIG. 14 is an (isometric) schematic diagram illustrating a perspective view of an exemplary specific preferred embodiment of the work piece imaging and milling detection unit, and main components thereof, in relation to the ion beam unit, the work piece manipulating and positioning unit, the component imaging unit, and all these in relation to the work piece, as part of the system illustrated in FIGS. 12 and 13, in accordance with the present invention;

FIG. 15 is an (isometric) schematic diagram illustrating a perspective view of an exemplary specific preferred embodiment of the work piece manipulating and positioning unit, and main components thereof, particularly showing close-up views of the work piece holder assembly without a work piece (a), and with a work piece (b), as part of the system illustrated in FIGS. 12 and 13, in accordance with the present invention;

FIG. 16 is a schematic diagram illustrating a combined cross-section view (upper part (a)) and top view (lower part (b)) of using the exemplary specific preferred embodiment of the work piece imaging and milling detection unit, and main components thereof, along with the ion beam unit, and the work piece manipulating and positioning unit, as part of the system illustrated in FIGS. 11, 12, and 13, in relation to the work piece, illustrated in FIG. 14, for determining and controlling extent of ion beam milling of a work piece, in accordance with the present invention; and

FIGS. 17a and 17b are schematic diagrams illustrating a cross-section view of determining depth of a target within a milled work piece, as part of determining and controlling extent of ion beam milling of a work piece, using the transmitted electron detector assembly included in the work piece imaging and milling detection unit illustrated in FIGS. 14 and 16, in accordance with the present invention.

### DESCRIPTION OF THE PREFERRED EMBODIMENTS

The present invention relates to ion beam milling of a surface, and more particularly, to a method, device, and system, for directed multi-deflected ion beam milling of a work piece, and, determining and controlling extent thereof. The present invention is generally applicable in a wide variety of different fields, such as semiconductor manufacturing, micro-analytical testing, materials science, metrology, lithography, micro-machining, and nanofabrication. The present invention is generally implementable in a wide variety of different applications of ion beam milling of a wide variety of different types of work pieces. The present invention is particularly implementable in a variety of different applications of preparing or/and analyzing a wide variety of different types of work pieces, particularly in the form of samples or materials, such as those derived from semiconductor wafers or chips, that are widely used in the above indicated exemplary fields.

A main aspect of the present invention is provision of a method for directed multi-deflected ion beam milling of a work piece, including the following main steps, and, components and functionalities thereof: providing an ion beam; and directing and at least twice deflecting the provided ion beam, for forming a directed multi-deflected ion beam, wherein the directed multi-deflected ion beam is directed towards, incident and impinges upon, and mills, a surface of the work piece.

Another main aspect of the present invention is a sub-combination of the method for directed multi-deflected ion beam milling of a work piece, whereby there is provision of a method for directed multi-deflecting a provided ion beam, including the following main steps, and, components and functionalities thereof: directing and at least twice deflecting the provided ion beam, for forming a directed multi-deflected ion beam, by deflecting and directing the provided ion beam, for forming a directed once deflected ion beam, and, deflecting and directing the directed once deflected ion beam, for forming a directed twice deflected ion beam being a type of the directed multi-deflected ion beam.

Another main aspect of the present invention is provision of a device for directed multi-deflected ion beam milling of a work piece, including the following main components and functionalities thereof: an ion beam source assembly, for providing an ion beam; and an ion beam directing and multi-deflecting assembly, for directing and at least twice deflecting the provided ion beam, for forming a directed multi-deflected ion beam, wherein the directed multi-deflected ion beam is directed towards, incident and impinges upon, and mills, a surface of the work piece.

Another main aspect of the present invention is a sub-combination of the device for directed multi-deflected ion beam milling of a work piece, whereby there is provision of a device for directed multi-deflecting a provided ion beam, including the following main components and functionalities thereof: an ion beam directing and multi-deflecting assembly, for directing and at least twice deflecting the provided ion beam, for forming a directed multi-deflected ion beam, wherein the ion beam directing and multi-deflecting assembly includes an ion beam first deflecting assembly, for deflecting and directing the provided ion beam, for forming a directed once deflected ion beam, and an ion beam second deflecting assembly, for deflecting and directing the directed once deflected ion beam, for forming a directed twice deflected ion beam being a type of the directed multi-deflected ion beam.

Another main aspect of the present invention is provision of a system for directed multi-deflected ion beam milling of a work piece, including the following main components and functionalities thereof: an ion beam unit, wherein the ion beam unit includes an ion beam source assembly, for providing an ion beam, and an ion beam directing and multi-deflecting assembly, for directing and at least twice deflecting the provided ion beam, for forming a directed multi-deflected ion beam, wherein the directed multi-deflected ion beam is directed towards, incident and impinges upon, and mills, a surface of the work piece; and a vacuum unit, operatively connected to the ion beam unit, for providing and maintaining a vacuum environment for the ion beam unit and the work piece. Preferably, the vacuum unit includes the work piece.

Preferably, the system further includes electronics and process control utilities, operatively connected to the ion beam unit and to the vacuum unit, for providing electronics to, and enabling process control of, the ion beam unit and the vacuum unit. Optionally, and preferably, the system further includes at least one additional unit selected from the group consisting of: a work piece imaging and milling detection unit, a work piece manipulating and positioning unit, an anti-vibration unit, a component imaging unit, and at least one work piece analytical unit, wherein each additional unit is operatively connected to the vacuum unit. Preferably, the electronics and process control utilities is also operatively connected to each additional unit, for providing electronics to, and enabling process control of, each additional unit, in a manner operatively integrated with the ion beam unit and the vacuum unit.

Another main aspect of the present invention is a sub-combination of the system for directed multi-deflected ion beam milling of a work piece, whereby there is provision of a system for directed multi-deflecting a provided ion beam, including the following main components and functionalities thereof: an ion beam unit, wherein the ion beam unit includes an ion beam directing and multi-deflecting assembly, for directing and at least twice deflecting the provided ion beam, for forming a directed multi-deflected ion beam, the ion beam directing and multi-deflecting assembly includes an ion beam first deflecting assembly, for deflecting and directing the provided ion beam, for forming a directed once deflected ion beam, and an ion beam second deflecting assembly, for deflecting and directing the directed once deflected ion beam, for forming a directed twice deflected ion beam being a type of the multi-deflected ion beam; and an ion beam second deflecting assembly, for deflecting and directing the directed once deflected ion beam, for forming a directed twice deflected ion beam being a type of the multi-deflected ion beam; and a vacuum unit, operatively connected to the ion beam unit, for providing and maintaining a vacuum environment for the ion beam unit.

Preferably, the system further includes electronics and process control utilities, operatively connected to the ion beam unit and to the vacuum unit, for providing electronics to, and enabling process control of, the ion beam unit and the vacuum unit. Optionally, and preferably, the system further includes at least one additional unit selected from the group consisting of: a work piece imaging and milling detection unit, a work piece manipulating and positioning unit, an anti-vibration unit, a component imaging unit, and at least one work piece analytical unit, wherein each additional unit is operatively connected to the vacuum unit. Preferably, the electronics and process control utilities is also operatively connected to each additional unit, for providing electronics to, and enabling process control of, each additional unit, in a manner operatively integrated with the ion beam unit and the vacuum unit.

Another main aspect of the present invention is provision of a method for determining and controlling extent of ion beam milling of a work piece, including the following main steps, and, components and functionalities thereof: providing a set of pre-determined values of at least one parameter of the work piece selected from the group consisting of: thickness of the work piece, depth of a target within the work piece, and topography of at least one surface of the work piece; performing directed multi-deflected ion beam milling of the work piece using a method for the directed multi-deflected ion beam milling of a work piece, including the following main steps, and, components and functionalities thereof: providing an ion beam; and directing and at least twice deflecting the provided ion beam, for forming a directed multi-deflected ion beam, wherein the directed multi-deflected ion beam is directed towards, incident and impinges upon, and mills, a surface of the work piece; real time measuring in-situ the at least one parameter of the work piece, for forming a set of measured values of the at least one parameter; comparing the set of the measured values to the provided set of the pre-determined values, for forming a set of value differences associated with the comparing; feeding back the set of the value differences for continuing the performing directed multi-deflected ion beam milling of the work piece, until the value differences are within a pre-determined range.

In the method, the degree of selectivity of the at least one surface of the work piece corresponds to the topography as being one of the pre-determined parameters of the work piece.

Accordingly, the present invention is based on a unique method, device, and system, and sub-combinations thereof, for directed multi-deflected ion beam milling of a work piece, and, determining and controlling extent thereof.

It is to be understood that the present invention is not limited in its application to the details of the order or sequence, and number, of procedures, steps, and sub-steps, of operation or implementation, or to the details of type, composition, construction, arrangement, order, and number, of the system units, sub-units, devices, assemblies, sub-assemblies, mechanisms, structures, components, elements, and, peripheral equipment, utilities, accessories, and materials, set forth in the following illustrative description and accompanying drawings, unless otherwise specifically stated herein. The present invention is capable of other embodiments and of being practiced or carried out in various ways. Although procedures, steps, sub-steps, and system units, sub-units, devices, assemblies, sub-assemblies, mechanisms, structures, components, elements, and, peripheral equipment, utilities, accessories, and materials, similar or equivalent to those illustratively described herein can be used for practicing or testing the present invention, suitable procedures, steps, sub-steps, and system units, sub-units, devices, assemblies, sub-assemblies, mechanisms, structures, components, elements, and, peripheral equipment, utilities, accessories, and materials, are illustratively described herein.

It is also to be understood that all technical and scientific words, terms, or/and phrases, used herein throughout the present disclosure have either the identical or similar meaning as commonly understood by one of ordinary skill in the art to which this invention belongs, unless otherwise specifically defined or stated herein. Phraseology, terminology, and, notation, employed herein throughout the present disclosure are for the purpose of description and should not be regarded as limiting. It is to be fully understood that, unless specifically stated otherwise, the phrase ‘operatively connected’ is generally used herein, and equivalently refers to the corresponding synonymous phrases ‘operatively joined’, and ‘operatively attached’, where the operative connection, operative joint, or operative attachment is according to a physical, or/and electrical, or/and electronic, or/and mechanical, or/and electromechanical, manner or nature, involving various types and kinds of hardware or/and software equipment and components. Moreover, all technical and scientific words, terms, or/and phrases, introduced, defined, described, or/and exemplified, in the above Background section, are equally or similarly applicable in the illustrative description of the preferred embodiments, examples, and appended claims, of the present invention.

In particular, in the scope and context of the present invention, with respect to the phrase ‘work piece’, herein, in a non-limiting manner, work piece generally refers to any of a wide variety of different types of materials, such as semiconductor materials, ceramic materials, pure metallic materials, metal alloy materials, polymeric materials, composite materials thereof, or materials derived therefrom.

For example, for a work piece being a semiconductor type of material, the work piece is typically in the form of a sample derived from a single die (of a wafer), a wafer segment, or a whole wafer. Ordinarily, such a work piece (sample) is pre-prepared using a micro-analytical sample preparation technique, for example, such as that disclosed in U.S. Provisional Patent Application No. 60/649,080, filed Feb. 3, 2005, entitled: “Sample Preparation For Micro-analysis”, assigned to the present applicant/assignee. Pre-preparing the work piece (sample) using a micro-analytical sample preparation technique is based on ‘sectioning’ or ‘segmenting’ at least a part of the work piece (sample) precursor, via reducing or thinning at least one dimension (length, width, or/and thickness, depth or height) of the size of the work piece (sample) precursor, by using one or more types of a cutting, cleaving, slicing, or/and polishing, procedure, thereby producing a prepared work piece (sample) ready for subjection to another process, for example, ion beam milling. Such a prepared work piece (sample) has at least one dimension (length, width, or/and thickness, depth or height) in a range of between about 10 microns and about 50 microns, and another dimension in a range of between about 2 millimeters and about 3 millimeters.

In particular, with respect to the phrase ‘ion beam milling of a work piece’, herein, ion beam milling of a work piece generally refers to impinging an ion beam onto a surface of the work piece, whereby interaction of the ion beam with the surface leads to removal of material from the surface, and therefore, from the work piece. In general, focused ion beam (FIB) milling refers to a highly energetic, concentrated, and well focused, ion beam, originating from a liquid metal source, such as liquid gallium, which is incident and impinges upon, and mills, a surface of a work piece, whereby interaction of the focused ion beam with the surface leads to removal of material from the surface of the work piece. In general, broad ion beam (BIB) milling refers to a less energetic and less focused, broad ion beam, originating from an inert gas source, such as argon or xenon, which is incident and impinges upon, and mills, the surface of a work piece, whereby interaction of the broad ion beam with the surface leads to removal of material from the surface of the work piece.

In general, ion beam milling involving an ion beam incident and impinging upon a surface of a work piece, whereby interaction of the ion beam with the surface leads to a ‘selective’ type of removal of material from the surface, can be considered ion beam ‘etching’. In the scope and context of the present invention, herein, ion beam milling generally refers to an ion beam incident and impinging upon a surface of a work piece, whereby interaction of the ion beam with the surface leads to a non-selective, or a selective, type of removal of material from the surface of the work piece.

In particular, with respect to the phrase ‘directing an ion beam’, the term ‘directing’ is generally equivalent to the synonymous terms guiding, regulating, controlling, and associated different grammatical forms thereof. Thus, directing an ion beam is generally equivalent to guiding, regulating, or controlling, an ion beam. In general, a directed, guided, regulated, or controlled, ion beam is directed, guided, regulated, or controlled, in or along a direction, path, axis, or trajectory, toward an object, entity, or target, herein, generally referred to as a work piece.

In particular, with respect to the phrase ‘deflecting an ion beam’, the term ‘deflecting’ is generally equivalent to the synonymous terms swerving, turning aside, bending, deviating, or alternatively, to the synonymous phrases to cause to swerve, to cause to turn aside, to cause to bend, to cause to deviate, respectively, and associated different grammatical forms thereof. Thus, deflecting an ion beam is generally equivalent to swerving, turning aside, bending, or deviating, an ion beam, or alternatively, causing an ion beam to swerve, turn aside, bend, or deviate, respectively, or alternatively, causing an ion beam to be swerved, turned aside, bent, or deviated, respectively, resulting in swerving, turning aside, bending, or deviating, respectively, of the ion beam. In general, an ion beam is deflected, caused to swerve, turned aside, bent, or deviated, from a first direction, path, axis, or trajectory, to a second direction, path, axis, or trajectory, respectively.

Accordingly, based on the preceding description, meaning, and understanding, of the phrase ‘deflecting an ion beam’, herein, the phrase ‘multi-deflecting an ion beam’ generally refers to deflecting an ion beam more than once, in particular, at least twice, and in general, any number of times more than once, corresponding to a plurality or multiple of times, thus, the term ‘multi-deflecting’. As a first specific example or embodiment of the present invention, deflecting an ion beam two times or twice, is herein referred to by the phrase ‘twice deflecting an ion beam’. As a second specific example or embodiment of the present invention, deflecting an ion beam three times or thrice, is herein referred to by the phrase ‘thrice deflecting an ion beam’. Thus, in general, for describing the present invention, deflecting an ion beam at least two times, is herein referred to by the phrase ‘at least twice deflecting an ion beam’, or, equivalently, ‘multi-deflecting an ion beam’. It is to be fully understood that the present invention is not at all limited to multi-deflecting an ion beam by twice or thrice deflecting the ion beam. In general, the present invention can be implemented wherein multi-deflecting an ion beam involves deflecting the ion beam more than three times, more than four times, etc.

In a corresponding manner, herein, the phrase ‘multi-deflected ion beam’ refers to an ion beam deflected more than once, in particular, at least twice, and in general, any number of times more than once, corresponding to a plurality or multiple of times, thus, the term ‘multi-deflected’. As a corresponding first specific example or embodiment of the present invention, an ion beam deflected two times or twice, is herein referred to by the phrase ‘twice deflected ion beam’. As a corresponding second specific example or embodiment of the present invention, an ion beam deflected three times or thrice, is herein referred to by the phrase ‘thrice deflected ion beam’. Thus, in a corresponding manner, in general, for describing the present invention, an ion beam deflected at least two times, is herein referred to by the phrase ‘multi-deflected ion beam’, being equivalent to the phrase ‘at least twice deflected ion beam’. It is to be fully understood that the present invention is not at all limited to a multi-deflected ion beam being a twice or thrice deflected ion beam. In general, the present invention can be implemented wherein a multi-deflected ion beam is an ion beam deflected more than three times, more than four times, etc.

Accordingly, based on the preceding description, meaning, and understanding, of the phrases ‘directing an ion beam’ and ‘deflecting an ion beam’, herein, the phrase ‘directing and at least twice deflecting an ion beam’ generally refers to directing an ion beam before, during, and after, being deflected more than once, in particular, at least twice, and in general, any number of times more than once. As a first specific example or embodiment of the present invention, directing an ion beam, followed by deflecting the directed ion beam two times or twice, and then directing the twice deflected ion beam, is herein referred to by the phrase ‘directing and at least twice deflecting an ion beam’. As a second specific example or embodiment of the present invention, directing an ion beam, followed by deflecting the directed ion beam three times or thrice, is herein referred to by the phrase ‘directing and thrice deflecting an ion beam’. Thus, in general, for describing the present invention, deflecting an ion beam at least two times, is herein referred to by the phrase ‘directing and at least twice deflecting an ion beam’, or, equivalently, ‘directing and multi-deflecting an ion beam’. It is to be fully understood that the present invention is not at all limited to directing and multi-deflecting an ion beam by directing and twice or thrice deflecting the ion beam. In general, the present invention can be implemented wherein directing and multi-deflecting an ion beam involves directing and deflecting the ion beam more than three times, more than four times, etc.

In a corresponding manner, herein, the phrase ‘directed multi-deflected ion beam’ refers to an ion beam which is directed before, during, and after, being deflected more than once, in particular, at least twice, and in general, any number of times more than once, corresponding to a plurality or multiple of times, thus, the phrase ‘directed multi-deflected’. As a corresponding first specific example or embodiment of the present invention, an ion beam directed before, during, and after, being deflected two times or twice, is herein referred to by the phrase ‘directed twice deflected ion beam’. As a corresponding second specific example or embodiment of the present invention, an ion beam directed before, during, and after, being deflected three times or thrice, is herein referred to by the phrase ‘directed thrice deflected ion beam’. Thus, in a corresponding manner, in general, for describing the present invention, an ion beam directed before, during, and after, being deflected at least two times, is herein referred to by the phrase ‘directed multi-deflected ion beam’, being equivalent to the phrase ‘directed at least twice deflected ion beam’. It is to be fully understood that the present invention is not at all limited to a directed multi-deflected ion beam being a directed twice or thrice deflected ion beam. In general, the present invention can be implemented wherein a directed multi-deflected ion beam is an ion beam directed before, during, and after, being deflected more than three times, more than four times, etc.

In particular, with respect to the phrase ‘rotating a directed multi-deflected (at least twice deflected) ion beam’, herein, the term ‘rotating’ is generally equivalent to the synonymous terms turning or spinning on, around, or relative to, an axis, or alternatively, to the synonymous phrases to cause to turn, or to cause to spin, respectively, on, around, or relative to, an axis, and associated different grammatical forms thereof. Thus, rotating a directed multi-deflected (at least twice deflected) ion beam is generally equivalent to turning or spinning, a directed multi-deflected (at least twice deflected) ion beam, on, around, or relative to, an axis, or alternatively, causing a directed multi-deflected (at least twice deflected) ion beam to turn or spin, respectively, on, around, or relative to, an axis, or alternatively, causing a directed multi-deflected (at least twice deflected) ion beam to be turned or spun, respectively, on, around, or relative to, an axis, resulting in turning or spinning, respectively, of the directed multi-deflected (at least twice deflected) ion beam, on, around, or relative to, an axis.

In general, a directed multi-deflected (at least twice deflected) ion beam is rotated (rotates), turned (turns), spun (spins), on, around, or relative to, an axis, where the axis is either an axis of the ion beam, or an axis of an element or component which ordinarily shares the same spatial and temporal domains as the ion beam. Moreover, such rotating, turning, or spinning, of a directed multi-deflected (at least twice deflected) ion beam on, around, or relative to, an axis, corresponds to angularly displacing the directed multi-deflected (at least twice deflected) ion beam on, around, or relative to, an axis, where the axis is either an axis of the ion beam, or an axis of an element or component which ordinarily shares the same spatial and temporal domains as the ion beam.

Additionally, as used herein, the term ‘about’ refers to.±10% of the associated value.

Procedures, steps, sub-steps, system units, system sub-units, devices, assemblies, sub-assemblies, mechanisms, structures, components, and elements, and, peripheral equipment, utilities, accessories, and materials, as well as operation and implementation, of exemplary preferred embodiments, alternative preferred embodiments, specific configurations, and, additional and optional aspects, characteristics, or features, thereof, of the present invention, are better understood with reference to the following illustrative description and accompanying drawings. Throughout the following illustrative description and accompanying drawings, same reference numbers, and letters, refer to same system units, sub-units, devices, assemblies, sub-assemblies, mechanisms, structures, components, and elements, and, peripheral equipment, utilities, accessories, and materials.

In the following illustrative description of the present invention, included are main or principal procedures, steps, and sub-steps, and, main or principal system units, system sub-units, devices, assemblies, sub-assemblies, mechanisms, structures, components, and elements, and, peripheral equipment, utilities, accessories, and materials, needed for sufficiently understanding proper ‘enabling’ utilization and implementation of the disclosed invention. Accordingly, description of various possible preliminary, intermediate, minor, or/and optional, procedures, steps, or/and sub-steps, or/and, system units, system sub-units, devices, assemblies, sub-assemblies, mechanisms, structures, components, and elements, and, peripheral equipment, utilities, accessories, and materials, of secondary importance with respect to enabling implementation of the invention, which are readily known by one of ordinary skill in the art, or/and which are available in the prior art and technical literature relating to the invention, are at most only briefly indicated herein.

In the following illustrative description of the present invention, in a non-limiting manner, the general order of presentation is as follows: the method for directed multi-deflected ion beam milling of a work piece; the method for directed multi-deflecting a provided ion beam, as a sub-combination of the method for directed multi-deflected ion beam milling of a work piece; the device for directed multi-deflected ion beam milling of a work piece; the device for directed multi-deflecting a provided ion beam, as a sub-combination of the device for directed multi-deflected ion beam milling of a work piece; the system for directed multi-deflected ion beam milling of a work piece; the system for directed multi-deflecting a provided ion beam, as a sub-combination of the system for directed multi-deflected ion beam milling of a work piece; and the method for determining and controlling extent of ion beam milling of a work piece.

Thus, a main aspect of the present invention is provision of a method for directed multi-deflected ion beam milling of a work piece, including the following main steps, and, components and functionalities thereof: providing an ion beam; and directing and at least twice deflecting the provided ion beam, for forming a directed multi-deflected ion beam, wherein the directed multi-deflected ion beam is directed towards, incident and impinges upon, and mills, a surface of the work piece.

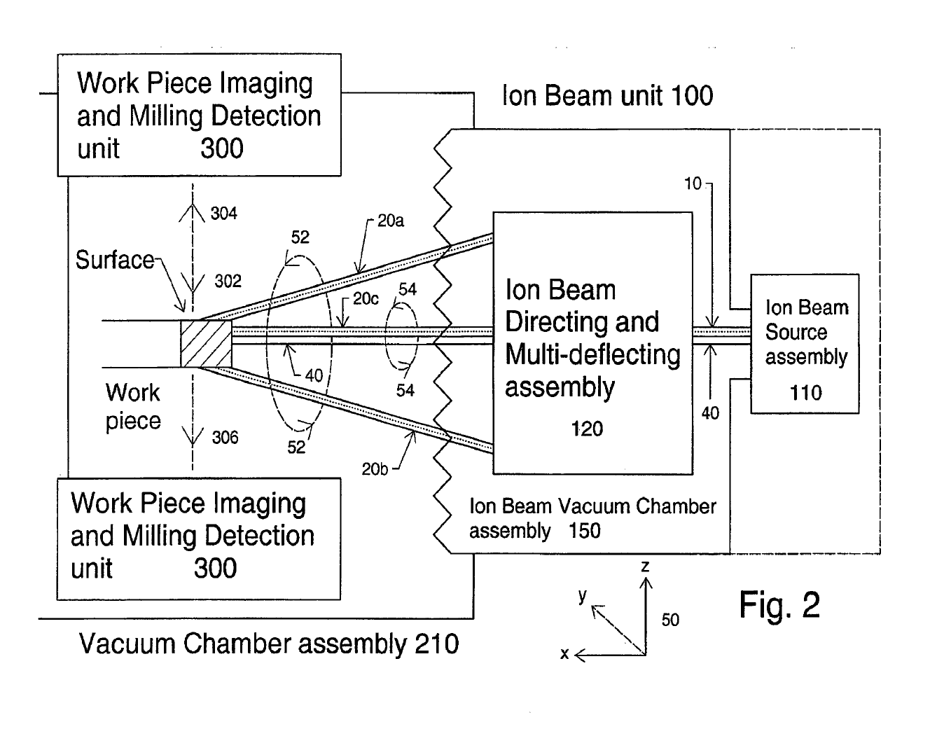

Referring now to the drawings, FIG. 2 is a schematic diagram illustrating a side view of an exemplary preferred embodiment of directed multi-deflected ion beam milling of a work piece, and, determining and controlling extent thereof, particularly showing the ion beam unit 100 in relation to the work piece imaging and milling detection unit 300 and the vacuum chamber assembly 210 of the vacuum unit, and all these in relation to the work piece and a surface thereof.

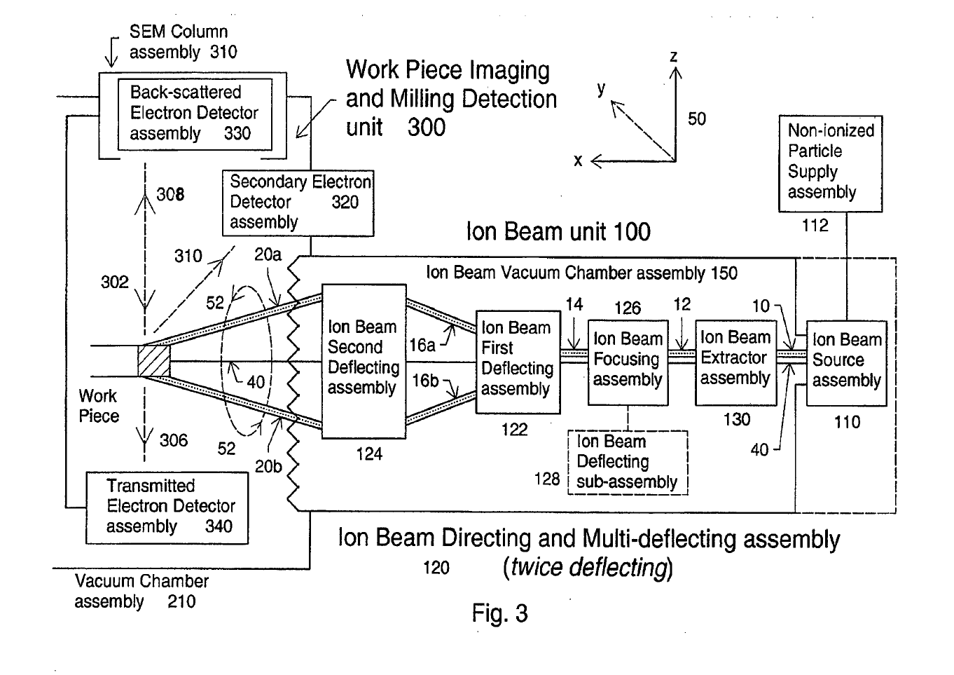

In general, FIG. 2 is completely sufficient for illustratively describing the method for directed multi-deflected ion beam milling of a work piece, of the present invention. However, for assuring understanding thereof, additional reference is made at this point to FIGS. 3, 4, 5, 6, 8, 9, and 10, which may also be referred to for understanding implementation of the numerous different exemplary specific preferred embodiments of the method for directed multi-deflected ion beam milling of a work piece, in accordance with the present invention.

FIG. 3 is a schematic diagram illustrating a side view of a more detailed version of the exemplary preferred embodiment illustrated in FIG. 2, particularly showing an exemplary specific preferred embodiment of the device, being the ion beam unit 100, including the ion beam directing and multi-deflecting assembly 120, for twice deflecting an ion beam 10, and showing an exemplary specific preferred embodiment of the work piece imaging and milling detection unit 300.

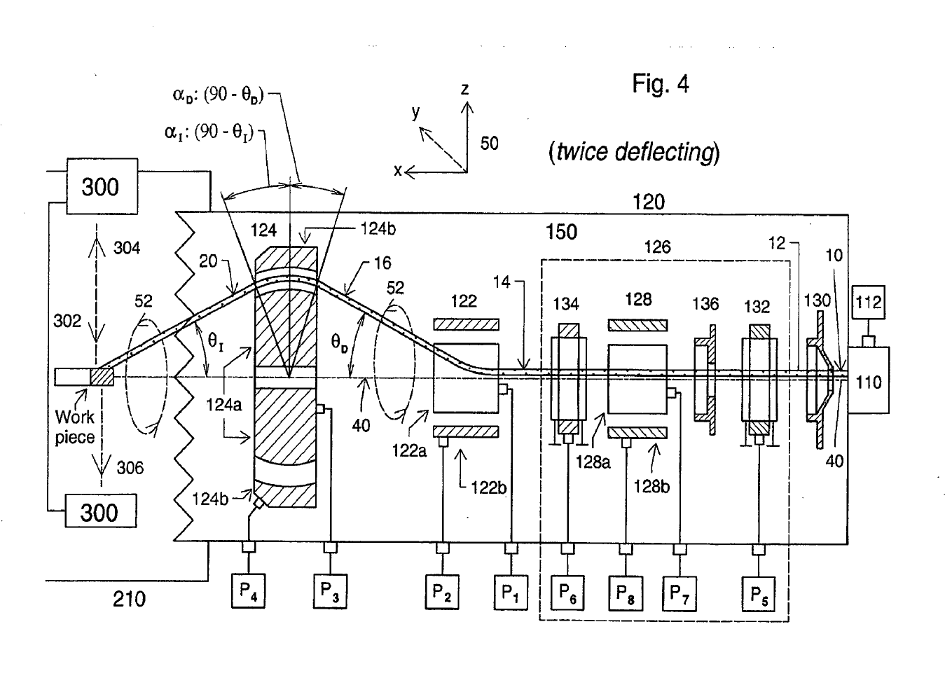

FIG. 4 is a schematic diagram illustrating a side view of the directed multi-deflected ion beam milling of a work piece, and, determining and controlling extent thereof, illustrated in FIGS. 2 and 3, particularly showing a cross-sectional side view of a more detailed component level version of the device, being the ion beam unit 100, including the ion beam directing and multi-deflecting assembly 120, structured and functional for twice deflecting an ion beam 10.

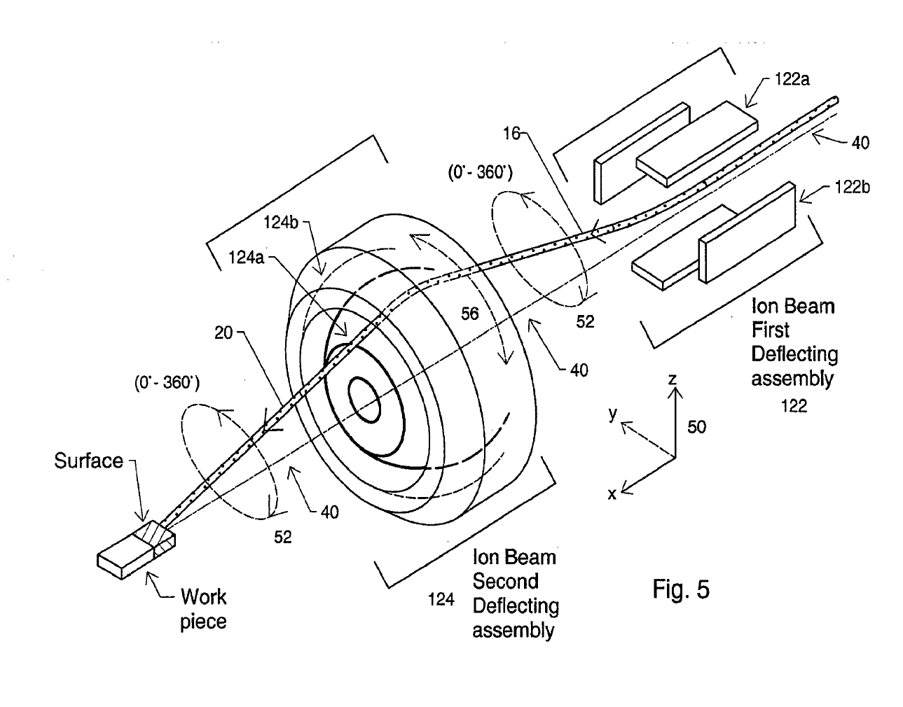

FIG. 5 is a schematic diagram illustrating a perspective view of the directed multi-deflected ion beam milling of a work piece, illustrated in FIGS. 2, 3, and 4, particularly showing an exemplary specific preferred embodiment of each of the ion beam first deflecting assembly 122 and the ion beam second deflecting assembly 124, included in the ion beam directing and multi-deflecting assembly 120 of the ion beam unit 100, structured and-functional for twice deflecting an ion beam 10.

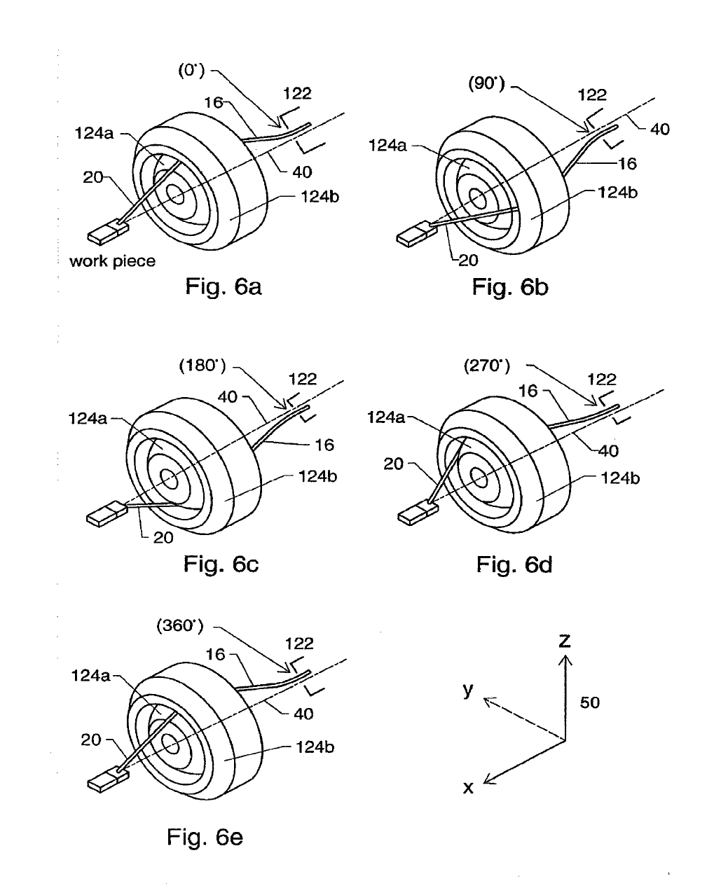

FIGS. 6a-6e are schematic diagrams together illustrating a perspective view of a rotational (angular) sequence of an ion beam directed and multi-deflected, relative to an arbitrarily assigned longitudinal axis 40 coaxial with the work piece, by the first ion beam deflecting assembly 122 and the second ion beam deflecting assembly 124a and 124b, corresponding to a directed twice deflected ion beam type of directed multi-deflected ion beam 20 which rotates in a range of between 0 degrees and 360 degrees around the longitudinal axis 40, and is directed towards, incident and impinges upon, and mills, a surface of the work piece.

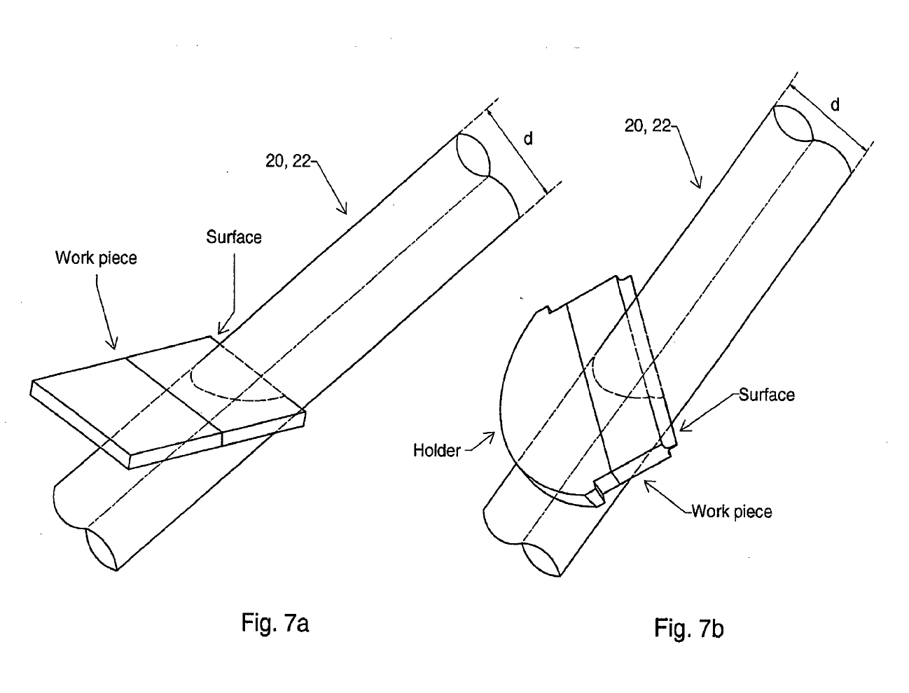

FIG. 7a is a schematic diagram illustrating a perspective close-up view of a directed multi-deflected ion beam 20 (twice deflected) or 22 (thrice deflected) directed towards, incident and impinging upon, and milling, a surface of a first type of an exemplary work piece (a generally shaped rectangular slab), particularly showing relative geometries and dimensions of ion beam 20 or 22, the surface, and the work piece.

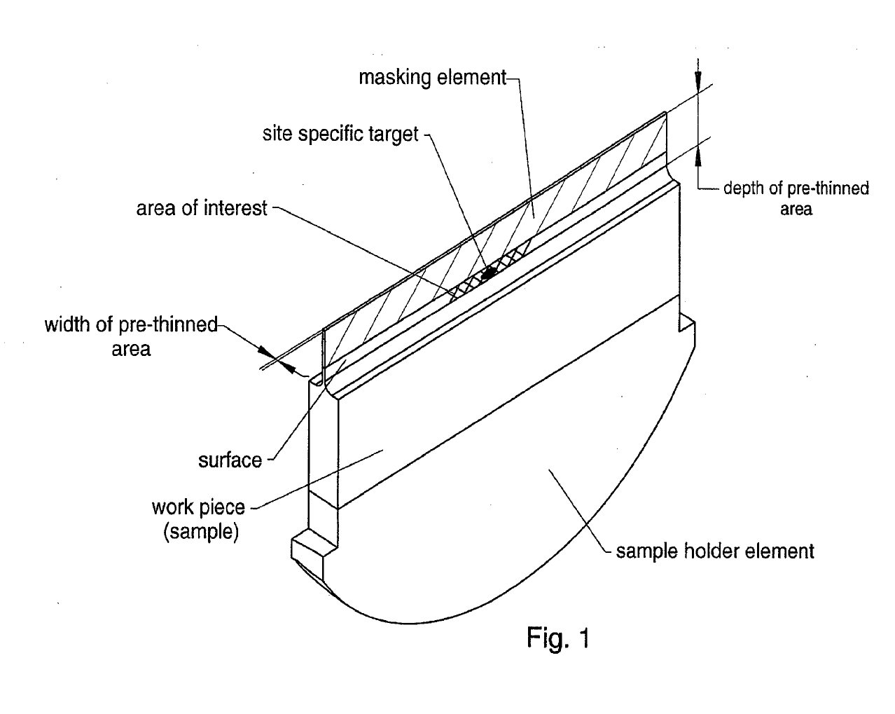

FIG. 7b is a schematic diagram illustrating a perspective close-up view of a directed multi-deflected ion beam 20 (twice deflected) or 22 (thrice deflected) directed towards, incident and impinging upon, and milling, a surface of a second type of an exemplary work piece (a typical sample of a portion of a semiconductor wafer or chip wherein the surface (with a mask) is held by a sample holder element, for example, similar to that illustrated in FIG. 1), particularly showing relative geometries and dimensions of ion beam 20 or 22, the surface, and the work piece.

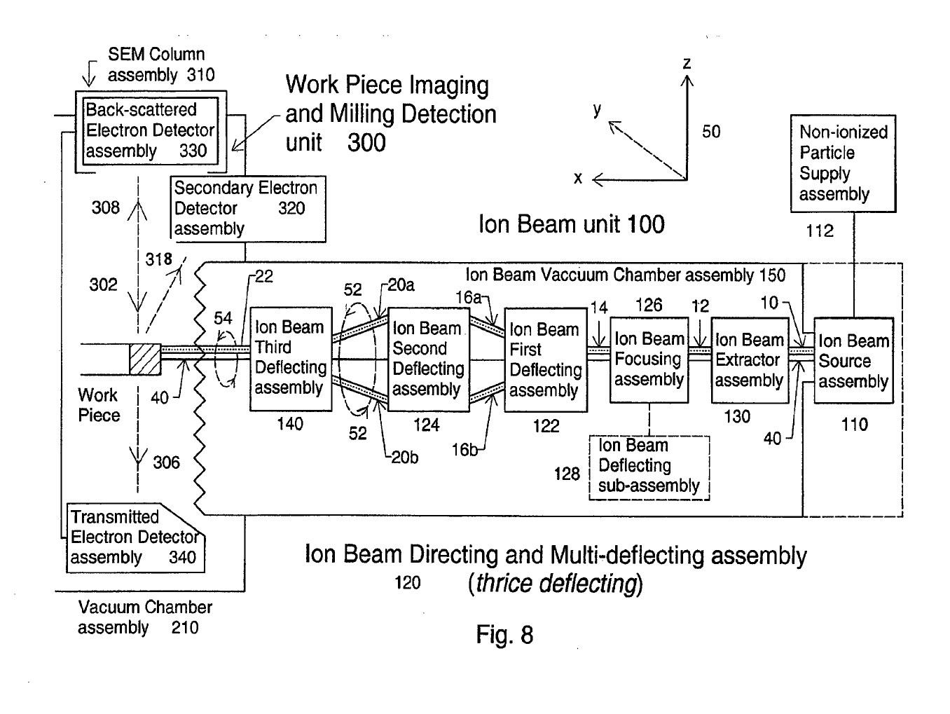

FIG. 8 is a schematic diagram illustrating a side view of a more detailed version of the exemplary preferred embodiment illustrated in FIG. 2, particularly showing an exemplary specific preferred embodiment of the ion beam unit 100, including the ion beam directing and multi-deflecting assembly 120, for thrice deflecting an ion beam 10, and an exemplary specific preferred embodiment of the work piece imaging and milling detection unit 300.

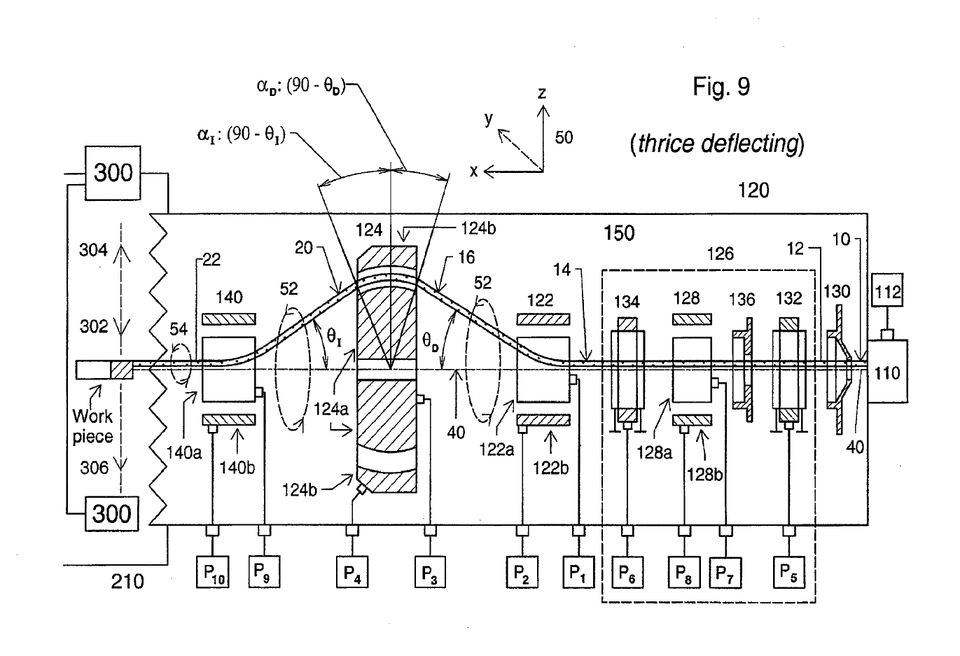

FIG. 9 is a schematic diagram illustrating a side view of the directed multi-deflected ion beam milling of a work piece, and, determining and controlling extent thereof, illustrated in FIGS. 2 and 8, particularly showing a cross-sectional side view of a more detailed component level version of the ion beam unit 100, including the ion beam directing and multi-deflecting assembly 120, structured and functional for twice deflecting an ion beam 10.

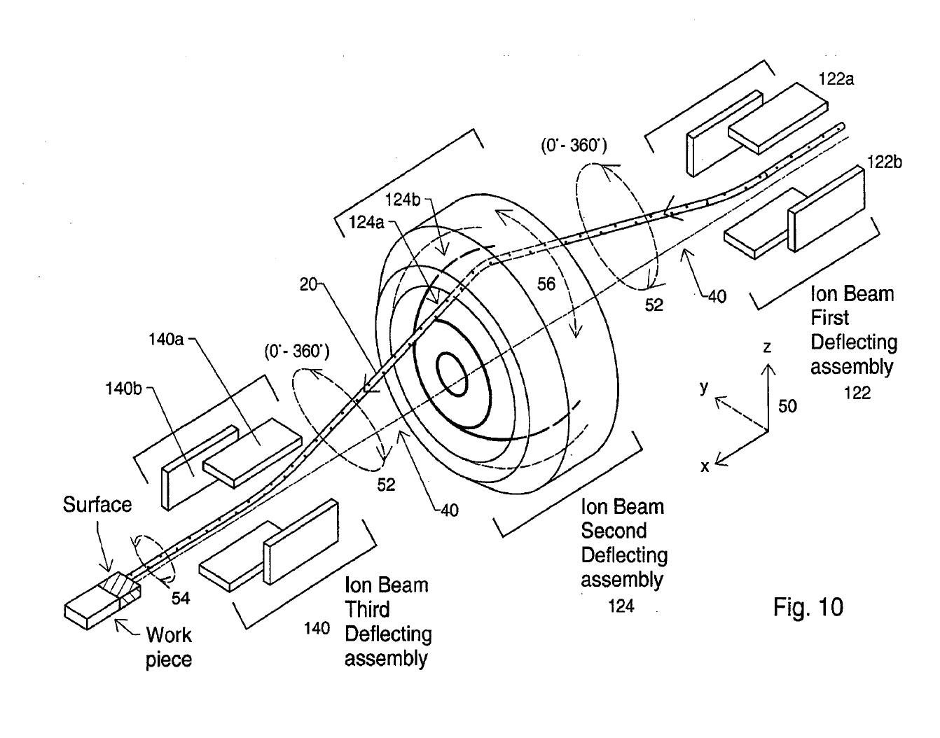

FIG. 10 is a schematic diagram illustrating a perspective view of the directed multi-deflected ion beam milling of a work piece, illustrated in FIGS. 2, 8, and 9, particularly showing an exemplary specific preferred embodiment of each of the ion beam first deflecting assembly 122, the ion beam second deflecting assembly 124, and the ion beam third deflecting assembly 140, included in the ion beam directing and multi-deflecting assembly 120 of the ion beam unit 100, structured and functional for thrice deflecting an ion beam.

Accordingly, with reference to FIG. 2, along with additional reference to FIGS. 3, 4, 5, 6, 8, 9, and 10, the method for directed multi-deflected ion beam milling of a work piece includes: providing an ion beam 10; and directing and at least twice (for example, twice or thrice) deflecting provided ion beam 10, for forming a directed multi-deflected ion beam 20a, 20b, or 20c, wherein directed multi-deflected ion beam 20a, 20b, or 20c, is directed towards, incident and impinges upon, and mills, a surface of the work piece.

In general, there are numerous different exemplary specific preferred embodiments of the method for directed multi-deflected ion beam milling of a work piece, in part, according to the specific spatial (directional, orientational, configurational) mode or manner, and according to the specific temporal (timing) mode or manner, of multi-deflecting and directing provided ion beam 10, wherein directed multi-deflected ion beam 20a, 20b, or 20c, is directed towards, incident and impinges upon, and mills, a surface of the work piece. In particular, the specific spatial (directional, orientational, configurational) mode or manner of multi-deflecting and directing provided ion beam 10 is linear or rotational. In particular, the specific temporal (timing) mode or manner, of multi-deflecting and directing provided ion beam 10, is continuous, discontinuous (periodic, aperiodic, or pulsed), or a combination of continuous and discontinuous (periodic, aperiodic, or pulsed). Moreover, each specific spatial (directional, orientational, configurational) mode or manner, that is, linear or rotational, of multi-deflecting and directing provided ion beam 10, can be implemented according to each specific temporal (timing) mode or manner, that is, continuous, discontinuous (periodic, aperiodic, or pulsed), or a combination of continuous and discontinuous (periodic, aperiodic, or pulsed), of multi-deflecting and directing provided ion beam 10.

More specifically, regarding the specific spatial (directional, orientational, configurational) mode or manner of multi-deflecting and directing provided ion beam 10, there is multi-deflecting (for example, twice or thrice deflecting) and linearly or rotationally directing provided ion beam 10, for forming a respective linearly or rotationally directed multi-deflected (twice or thrice deflected, respectively) ion beam 20a, 20b, or 20c, wherein the respective linearly or rotationally directed multi-deflected ion beam 20a, 20b, or 20c, is respectively linearly or rotationally directed towards, incident and impinges upon, and mills, a surface of the work piece.

More specifically, regarding the specific temporal (timing) mode or manner, of multi-deflecting and directing provided ion beam 10, there is multi-deflecting (for example, twice or thrice deflecting) and continuously, discontinuously, or, a combination of continuously and discontinuously, directing provided ion beam 10, for forming a respective continuously, discontinuously, or, a combination of continuously and discontinuously, directed multi-deflected (twice or thrice deflected, respectively) ion beam 20a, 20b, or 20c, wherein the respective continuously, discontinuously, or, a combination of continuously and discontinuously, directed multi-deflected ion beam 20a, 20b, or 20c, is respectively continuously, discontinuously, or, a combination of continuously and discontinuously, directed towards, incident and impinges upon, and mills, a surface of the work piece.

Accordingly, regarding each specific temporal (timing) mode or manner, of multi-deflecting and directing provided ion beam 10, implemented according to each specific temporal (timing) mode or manner, of multi-deflecting and directing provided ion beam 10, there is multi-deflecting (for example, twice or thrice deflecting) and continuously, discontinuously, or, a combination of continuously and discontinuously, linearly or rotationally directing provided ion beam 10, for forming a respective continuously, discontinuously, or, a combination of continuously and discontinuously, linearly or rotationally directed multi-deflected (twice or thrice deflected, respectively) ion beam 20a, 20b, or 20c, wherein the respective continuously, discontinuously, or, a combination of continuously and discontinuously, linearly or rotationally directed multi-deflected ion beam 20a, 20b, or 20c, is respectively continuously, discontinuously, or, a combination of continuously and discontinuously, linearly or rotationally directed towards, incident and impinges upon, and mills, a surface of the work piece.

Each of the above described (spatially and temporally characterized) exemplary specific preferred embodiments of the method for directed multi-deflected ion beam milling of a work piece, according to a different specific spatial (directional, orientational, configurational) mode or manner, and according to a different specific temporal (timing) mode or manner, of multi-deflecting (for example, twice or thrice deflecting) and directing provided ion beam 10, is illustratively described in more detail hereinbelow. For this, as shown in FIG. 2, it is generally applicable to each exemplary specific preferred embodiment that provided ion beam 10 is essentially coaxial with a longitudinal axis, herein, referred to as longitudinal axis 40. Additionally, as shown in FIG. 2, it is generally applicable to each exemplary specific preferred embodiment, that the work piece is essentially coaxial with longitudinal axis 40. With reference to exemplary three-dimensional xyz coordinate axes system 50, arbitrarily, longitudinal 40 extends in the direction of, along, and is coaxial with, the x-axis.

### Linear Spatial Modes or Manners of Ion Beam Milling of a Work Piece

With reference to FIG. 2, provided ion beam 10 is linearly directed and extends in the direction of, and along, longitudinal axis 40 [i.e., the x-axis (in z=0 domain)]. Then, linearly directed provided ion beam 10 is at least twice deflected (multi-deflected) and linearly directed, and is converted or transformed into, and becomes, linearly directed multi-deflected ion beam 20a, 20b, or 20c, which is linearly directed and extends in the direction from above longitudinal axis 40 [i.e., the x-axis (in positive z-axis domain)], or from below longitudinal axis 40 [i.e., the x-axis (in negative z-axis domain)], or in the direction of, and along, longitudinal axis 40 [i.e., the x-axis (in z=0 domain)], respectively, towards the work piece, followed by being incident and impinging upon, and milling, a surface of the work piece.

More specifically, the preceding description corresponds to three (linearly spatially characterized) main exemplary specific preferred embodiments of the method for directed multi-deflected ion beam milling of a work piece, each according to a different specific linear spatial (directional, orientational, configurational) mode or manner of multi-deflecting (for example, twice or thrice deflecting) and directing provided ion beam 10, wherein linearly directed multi-deflected ion beam 20a, 20b, or 20c, is linearly directed towards, incident and impinges upon, and mills, a surface of the work piece.

Moreover, each of these three (linearly spatially characterized) main exemplary specific preferred embodiments of the method for directed multi-deflected ion beam milling of a work piece, is implemented according to three main different specific temporal (timing) modes or manners of multi-deflecting (for example, twice or thrice deflecting) and linearly directing provided ion beam 10, selected from the group consisting of a continuous type of temporal (timing) mode or manner of multi-deflecting and linearly directing provided ion beam 10, a discontinuous (periodic, aperiodic, or pulsed) type of temporal (timing) mode or manner of multi-deflecting and linearly directing provided ion beam 10, and, a combination of a continuous type and a discontinuous type of temporal (timing) mode or manner of multi-deflecting and linearly directing provided ion beam 10, wherein linearly directed multi-deflected ion beam 20a, 20b, or 20c, is linearly directed towards, incident and impinges upon, and mills, a surface of the work piece. Such exemplary specific preferred embodiments of the method for directed multi-deflected ion beam milling of a work piece, are illustratively described immediately following.

In the first main (linearly spatially characterized) exemplary specific preferred embodiment, provided ion beam 10 is at least twice deflected (multi-deflected) and then linearly directed, for forming a linearly directed multi-deflected ion beam 20a, which is linearly directed and extends in the direction from above longitudinal axis 40 [i.e., the x-axis (in positive z-axis domain)], towards the work piece, followed by being incident and impinging upon, and milling, a surface of the work piece.

According to a continuous type of temporal (timing) mode or manner of multi-deflecting and linearly directing provided ion beam 10, provided ion beam 10 is temporally continuously at least twice deflected (multi-deflected) and then temporally continuously linearly directed, for forming a temporally continuously linearly directed multi-deflected ion beam 20a, which is temporally continuously linearly directed and extends in the direction from above longitudinal axis 40 [i.e., the x-axis (in positive z-axis domain)], towards the work piece, followed by being temporally continuously incident and impinging upon, and milling, a surface of the work piece.

According to a discontinuous type of temporal (timing) mode or manner of multi-deflecting and linearly directing provided ion beam 10, provided ion beam 10 is temporally discontinuously (periodically or aperiodically) at least twice deflected (multi-deflected) and then temporally discontinuously (periodically or aperiodically) linearly directed, for forming a temporally discontinuously (periodically or aperiodically) linearly directed multi-deflected ion beam 20a, which is temporally discontinuously (periodically or aperiodic ally) linearly directed and extends in the direction from above longitudinal axis 40 [i.e., the x-axis (in positive z-axis domain)], towards the work piece, followed by being temporally discontinuously (periodically or aperiodically) incident and impinging upon, and milling, a surface of the work piece.

According to a combination of a continuous type and a discontinuous type of temporal (timing) mode or manner of multi-deflecting and linearly directing provided ion beam 10, provided ion beam 10 is temporally continuously and discontinuously (periodically or aperiodically) at least twice deflected (multi-deflected) and then temporally continuously and discontinuously (periodically or aperiodically) linearly directed, for forming a temporally continuously and discontinuously (periodically or aperiodically) linearly directed multi-deflected ion beam 20a, which is temporally continuously and discontinuously (periodically or aperiodically) linearly directed and extends in the direction from above longitudinal axis 40 [i.e., the x-axis (in positive z-axis domain)], towards the work piece, followed by being temporally continuously and discontinuously (periodically or aperiodically) incident and impinging upon, and milling, a surface of the work piece.

In the second main (linearly spatially characterized) exemplary specific preferred embodiment, provided ion beam 10 is at least twice deflected (multi-deflected) and then linearly directed, for forming a linearly directed multi-deflected ion beam 20b, which is linearly directed and extends in the direction from below longitudinal axis 40 [i.e., the x-axis (in negative z-axis domain)], towards the work piece, followed by being incident and impinging upon, and milling, a surface of the work piece.

According to a continuous type of temporal (timing) mode or manner of multi-deflecting and directing provided ion beam 10, provided ion beam 10 is temporally continuously at least twice deflected (multi-deflected) and then temporally continuously linearly directed, for forming a temporally continuously linearly directed multi-deflected ion beam 20b, which is temporally continuously linearly directed and extends in the direction from below longitudinal axis 40 [i.e., the x-axis (in negative z-axis domain)], towards the work piece, followed by being temporally continuously incident and impinging upon, and milling, a surface of the work piece.

According to a discontinuous type of temporal (timing) mode or manner of multi-deflecting and directing provided ion beam 10, provided ion beam 10 is temporally discontinuously (periodically or aperiodically) at least twice deflected (multi-deflected) and then temporally discontinuously (periodically or aperiodically) linearly directed, for forming a temporally discontinuously (periodically or aperiodically) linearly directed multi-deflected ion beam 20b, which is temporally discontinuously (periodically or aperiodic ally) linearly directed and extends in the direction from below longitudinal axis 40 [i.e., the x-axis (in negative z-axis domain)], towards the work piece, followed by being temporally discontinuously (periodically or aperiodically) incident and impinging upon, and milling, a surface of the work piece.

According to a combination of a continuous type and a discontinuous type of temporal (timing) mode or manner of multi-deflecting and directing provided ion beam 10, provided ion beam 10 is temporally continuously and discontinuously (periodically or aperiodically) at least twice deflected (multi-deflected) and then temporally continuously and discontinuously (periodically or aperiodically) linearly directed, for forming a temporally continuously and discontinuously (periodically or aperiodically) directed multi-deflected ion beam 20b, which is temporally continuously and discontinuously (periodically or aperiodically) linearly directed and extends in the direction from below longitudinal axis 40 [i.e., the x-axis (in negative z-axis domain)], towards the work piece, followed by being temporally continuously and discontinuously (periodically or aperiodically) incident and impinging upon, and milling, a surface of the work piece.

In the third main (linearly spatially characterized) exemplary specific preferred embodiment, provided ion beam 10 is at least twice deflected (multi-deflected) and then linearly directed, for forming a linearly directed multi-deflected ion beam 20c, which is linearly directed and extends in the direction of, and along, longitudinal axis 40 [i.e., the x-axis (in z=0 domain)], and therefore, work piece axis 40, towards the work piece, followed by being incident and impinging upon, and milling, a surface of the work piece.

According to a continuous type of temporal (timing) mode or manner of multi-deflecting and linearly directing provided ion beam 10, provided ion beam 10 is temporally continuously at least twice deflected (multi-deflected) and then temporally continuously linearly directed, for forming a temporally continuously linearly directed multi-deflected ion beam 20c, which is temporally continuously linearly directed and extends in the direction of, and along, longitudinal axis 40 [i.e., the x-axis (in z=0 domain)], and therefore, work piece axis 40, towards the work piece, followed by being temporally continuously incident and impinging upon, and milling, a surface of the work piece.

According to a discontinuous type of temporal (timing) mode or manner of multi-deflecting and linearly directing provided ion beam 10, provided ion beam 10 is temporally discontinuously (periodically or aperiodically) at least twice deflected (multi-deflected) and then temporally discontinuously (periodically or aperiodically) linearly directed, for forming a temporally discontinuously (periodically or aperiodically) linearly directed multi-deflected ion beam 20c, which is temporally discontinuously (periodically or aperiodic ally) linearly directed and extends in the direction of, and along, longitudinal axis 40 [i.e., the x-axis (in z=0 domain)], towards the work piece, followed by being temporally discontinuously (periodically or aperiodically) incident and impinging upon, and milling, a surface of the work piece.

According to a combination of a continuous type and a discontinuous type of temporal (timing) mode or manner of multi-deflecting and linearly directing provided ion beam 10, provided ion beam 10 is temporally continuously and discontinuously (periodically or aperiodically) at least twice deflected (multi-deflected) and then temporally continuously and discontinuously (periodically or aperiodically) linearly directed, for forming a temporally continuously and discontinuously (periodically or aperiodically) linearly directed multi-deflected ion beam 20c, which is temporally continuously and discontinuously (periodically or aperiodically) linearly directed and extends in the direction of, and along, longitudinal axis 40 [i.e., the x-axis (in z=0 domain)], towards the work piece, followed by being temporally continuously and discontinuously (periodically or aperiodic ally) incident and impinging upon, and milling, a surface of the work piece.

### Rotational Spatial Modes or Manners of Ion Beam Milling of a Work Piece

With reference to FIG. 2, provided ion beam 10 is linearly directed and extends in the direction of, and along, longitudinal axis 40 [i.e., the x-axis (in z=0 domain)]. Then, linearly directed provided ion beam 10 is at least twice deflected (multi-deflected) and rotationally directed, and is converted or transformed into, and becomes, rotationally directed multi-deflected ion beam 20a or 20b, or 20c, which is rotationally directed and extends ‘conically’ or ‘conically-like’ (in FIG. 2, indicated by the large dashed line perspectively drawn circle 52), or ‘cylindrically’ (in FIG. 2, indicated by the small dashed line perspectively drawn circle 54), respectively, around longitudinal axis 40, towards the work piece, followed by being incident and impinging upon, and milling, a surface of the work piece.

More specifically, the preceding description corresponds to two (rotationally spatially characterized) main exemplary specific preferred embodiments of the method for directed multi-deflected ion beam milling of a work piece, each according to a different specific rotational spatial (directional, orientational, configurational) mode or manner of multi-deflecting (for example, twice or thrice deflecting) and directing provided ion beam 10, wherein rotationally directed multi-deflected ion beam 20a or 20b, or 20c, is rotationally directed towards, incident and impinges upon, and mills, a surface of the work piece.

Moreover, each of these two (rotationally spatially characterized) main exemplary specific preferred embodiments of the method for directed multi-deflected ion beam milling of a work piece, is implemented according to three main different specific temporal (timing) modes or manners of multi-deflecting (for example, twice or thrice deflecting) and rotationally directing provided ion beam 10, selected from the group consisting of a continuous type of temporal (timing) mode or manner of multi-deflecting and rotationally directing provided ion beam 10, a discontinuous (periodic, aperiodic, or pulsed) type of temporal (timing) mode or manner of multi-deflecting and rotationally directing provided ion beam 10, and, a combination of a continuous type and a discontinuous type of temporal (timing) mode or manner of multi-deflecting and rotationally directing provided ion beam 10, wherein rotationally directed multi-deflected ion beam 20a or 20b, or 20c, is rotationally directed towards, incident and impinges upon, and mills, a surface of the work piece. Such exemplary specific preferred embodiments of the method for directed multi-deflected ion beam milling of a work piece, are illustratively described immediately following.

In the first main (rotationally spatially characterized) exemplary specific preferred embodiment, provided ion beam 10 is at least twice deflected (multi-deflected) and then rotationally directed, for forming a rotationally directed multi-deflected ion beam 20a or 20b which is rotationally directed and extends ‘conically’ or ‘conically-like’ around longitudinal axis 40, towards the work piece, followed by being incident and impinging upon, and milling, a surface of the work piece.

According to a continuous type of temporal (timing) mode or manner of multi-deflecting and conically or conically-like rotationally directing provided ion beam 10, provided ion beam 10 is temporally continuously at least twice deflected (multi-deflected) and then temporally continuously rotationally directed, for forming a temporally continuously rotationally directed multi-deflected ion beam 20a or 20b, which is temporally continuously rotationally directed and extends conically or conically-like around longitudinal axis 40, towards the work piece, followed by being incident and impinging upon, and milling, a surface of the work piece.

According to a discontinuous type of temporal (timing) mode or manner of multi-deflecting and conically or conically-like rotationally directing provided ion beam 10, provided ion beam 10 is temporally discontinuously (periodically or aperiodically) at least twice deflected (multi-deflected) and then temporally discontinuously (periodically or aperiodic ally) rotationally directed, for forming a temporally discontinuously (periodically or aperiodically) rotationally directed multi-deflected ion beam 20a or 20b, which is temporally discontinuously (periodically or aperiodically) rotationally directed and extends conically or conically-like around longitudinal axis 40, towards the work piece, followed by being incident and impinging upon, and milling, a surface of the work piece.

According to a combination of a continuous type and a discontinuous type of temporal (timing) mode or manner of multi-deflecting and conically or conically-like rotationally directing provided ion beam 10, provided ion beam 10 is temporally continuously and discontinuously (periodically or aperiodically) at least twice deflected (multi-deflected) and then temporally continuously and discontinuously (periodically or aperiodically) rotationally directed, for forming a temporally continuously and discontinuously (periodically or aperiodically) rotationally directed multi-deflected ion beam 20a or 20b, which is temporally continuously and discontinuously (periodically or aperiodic ally) rotationally directed and extends conically or conically-like around longitudinal axis 40, towards the work piece, followed by being incident and impinging upon, and milling, a surface of the work piece.

In the second main (rotationally spatially characterized) exemplary specific preferred embodiment, provided ion beam 10 is at least twice deflected (multi-deflected) and then rotationally directed, for forming a rotationally directed multi-deflected ion beam 20c which is rotationally directed and extends ‘cylindrically’ around longitudinal axis 40, towards the work piece, followed by being incident and impinging upon, and milling, a surface of the work piece, wherein provided ion beam 10 is coaxial with longitudinal axis 40.

According to a continuous type of temporal (timing) mode or manner of multi-deflecting and cylindrically rotationally directing provided ion beam 10, provided ion beam 10 is temporally continuously at least twice deflected (multi-deflected) and then temporally continuously rotationally directed, for forming a temporally continuously rotationally directed multi-deflected ion beam 20c, which is temporally continuously rotationally directed and extends cylindrically around longitudinal axis 40, towards the work piece, followed by being incident and impinging upon, and milling, a surface of the work piece.

According to a discontinuous type of temporal (timing) mode or manner of multi-deflecting and cylindrically rotationally directing provided ion beam 10, provided ion beam 10 is temporally discontinuously (periodically or aperiodically) at least twice deflected (multi-deflected) and then temporally discontinuously (periodically or aperiodically) rotationally directed, for forming a temporally discontinuously (periodically or aperiodically) rotationally directed multi-deflected ion beam 20c, which is temporally discontinuously (periodically or aperiodically) rotationally directed and extends cylindrically around longitudinal axis 40, towards the work piece, followed by being incident and impinging upon, and milling, a surface of the work piece.

According to a combination of a continuous type and a discontinuous type of temporal (timing) mode or manner of multi-deflecting and cylindrically rotationally directing provided ion beam 10, provided ion beam 10 is temporally continuously and discontinuously (periodically or aperiodically) at least twice deflected (multi-deflected) and then temporally continuously and discontinuously (periodically or aperiodically) rotationally directed, for forming a temporally continuously and discontinuously (periodically or aperiodically) rotationally directed multi-deflected ion beam 20c, which is temporally continuously and discontinuously (periodically or aperiodically) rotationally directed and extends cylindrically around longitudinal axis 40, towards the work piece, followed by being incident and impinging upon, and milling, a surface of the work piece.

With reference to FIG. 2, regarding the above illustratively described two (rotationally spatially characterized) main exemplary specific preferred embodiments, and three temporal (timing) modes of implementing each thereof, of the method for directed multi-deflected ion beam milling of a work piece, the conically or conically-like rotationally directed multi-deflected ion beam 20a or 20b, is according to a clockwise direction, a counter-clockwise direction, or a combination of a clockwise direction and a counter-clockwise direction, around longitudinal axis 40 (circle 52).

Moreover, the clockwise direction, counter-clockwise direction, or combination of the clockwise direction and the counter-clockwise direction, of the conically or conically-like rotationally directed multi-deflected ion beam 20a or 20b around longitudinal axis 40 (circle 52), is according to a partial rotation, that is, greater than 0 degrees and less than 360 degrees, or/and according to at least one complete rotation, that is, equal to or greater than 360 degrees. Furthermore, such partial or/and complete rotation of the conically or conically-like rotationally directed multi-deflected ion beam 20a or 20b around longitudinal axis 40 (circle 52) is according to a back-and-forth rocking type of conical or conical-like rotational motion, or/and according to a continuous or/and discontinuous (periodic, aperiodic, or pulsed) oscillatory type of conical or conical-like rotational motion. Additionally, the conically or conically-like rotationally directed multi-deflected ion beam 20a or 20b, according to any of the just described clockwise direction, counter-clockwise direction, or combination of clockwise direction and counter-clockwise direction, rotational motions around longitudinal axis 40 (circle 52), generally, projects as a circle or ellipse.

The cylindrically rotationally directed multi-deflected ion beam 20c, is according to a clockwise direction, a counter-clockwise direction, or a combination of a clockwise direction and a counter-clockwise direction, around longitudinal axis 40 (circle 54). Additionally, for the cylindrically rotationally directed multi-deflected ion beam 20c, since longitudinal axis 40 is coaxial with provided ion beam 10, the clockwise direction or a counter-clockwise direction of rotation of cylindrically rotationally directed multi-deflected ion beam 20c, around longitudinal axis 40, is equivalent to clockwise direction or a counter-clockwise direction of rotation of cylindrically rotationally directed multi-deflected ion beam 20c around an axis of provided ion beam 10, and therefore, around an axis of cylindrically rotationally directed multi-deflected ion beam 20c.

Moreover, the clockwise direction, counter-clockwise direction, or combination of the clockwise direction and the counter-clockwise direction, of the cylindrically rotationally directed multi-deflected ion beam 20c around longitudinal axis 40 (circle 54), is according to a partial rotation, that is, greater than 0 degrees and less than 360 degrees, or/and according to at least one complete rotation, that is, equal to or greater than 360 degrees. Furthermore, such partial or/and complete rotation of the cylindrically rotationally directed multi-deflected ion beam 20c around longitudinal axis 40 (circle 54) is according to a back-and-forth rocking type of cylindrical rotational motion, or/and according to a continuous or/and discontinuous (periodic, aperiodic, or pulsed) oscillatory type of cylindrical rotational motion. Additionally, the cylindrically rotationally directed multi-deflected ion beam 20c, according to any of the just described clockwise direction, counter-clockwise direction, or combination of clockwise direction and counter-clockwise direction, cylindrical rotational motions around longitudinal axis 40 (circle 54), generally, projects as a circle.

### Main Parameters Characterizing the Directed Multi-deflected Ion Beam

With reference to FIG. 2, for the above illustratively described different exemplary specific preferred embodiments of the method for directed multi-deflected ion beam milling of a work piece, according to the specific linear or rotational spatial (directional, orientational, configurational) modes or manners, and according to the specific continuous or discontinuous temporal (timing) modes or manners, of multi-deflecting and directing provided ion beam 10, wherein directed multi-deflected ion beam 20a, 20b, or 20c, is directed towards, incident and impinges upon, and mills, a surface of the work piece, the following main parameters are applicable for characterizing directed multi-deflected ion beam 20a, 20b, or 20c, while directed towards, incident and impinging upon, and milling, a surface of the work piece.

Diameter or width of the ion beam: diameter or width of directed multi-deflected ion beam 20a, 20b, or 20c, while being directed towards, incident and impinging upon, and milling, a surface of the work piece. For a broad ion beam (BIB) type of ion beam milling of the work piece, the diameter or width of the ion beam is, preferably, in a range of between about 30 microns and about 2000 microns (2 millimeters), and more preferably, in a range of between about 200 microns and about 1000 microns (1 millimeter). For a focused ion beam (FIB) type of ion beam milling of the work piece, the diameter or width of the ion beam is, preferably, in a range of between about 5 nanometers and about 100 nanometers.

Intensity (energy) of the ion beam: intensity (energy) of directed multi-deflected ion beam 20a, 20b, or 20c, while being directed towards, incident and impinging upon, and milling, a surface of the work piece. Preferably, in a range of between about 0.5 keV (kilo-electron volts) and about 12 keV (kilo-electron volts), and more preferably, in a range of between about 1 keV and about 10 keV.

First time derivative of the intensity (energy) of the ion beam: d(ion beam intensity or energy)/dt, where t represents time. Rate of change of the intensity (energy) of directed multi-deflected ion beam 20a, 20b, or 20c, with time, corresponding to the temporal rate of change of the intensity (energy) of directed multi-deflected ion beam 20a, 20b, or 20c, while being directed towards, incident and impinging upon, and milling, a surface of the work piece.

Second time derivative of the intensity (energy) of the ion beam: d.sup.2(ion beam intensity or energy)/dt.sup.2, where t represents time. Rate of change of the first time derivative of the intensity (energy) of directed multi-deflected ion beam 20a, 20b, or 20c, corresponding to the temporal rate of change of the time derivative of the intensity (energy) of directed multi-deflected ion beam 20a, 20b, or 20c, while being directed towards, incident and impinging upon, and milling, a surface of the work piece.

Current density or flux of the ion beam: two dimensional (area) density or flux of the current of directed multi-deflected ion beam 20a, 20b, or 20c, expressed in units of current per unit cross-sectional area of directed multi-deflected ion beam 20a, 20b, or 20c, while being directed towards, incident and impinging upon, and milling, a surface of the work piece. Preferably, in a range of between about 0.08 mA/cm.sup.2 (milli-ampere per square centimeter) and about 500 mA/cm.sup.2 (milli-ampere per square centimeter), and more preferably, in a range of between about 0.1 mA/cm.sup.2 and about 30 mA/cm.sup.2.

Rotational angle or angular displacement of the ion beam: the angle of rotation or angular displacement of rotationally directed multi-deflected ion beam 20a, 20b, or 20c, around longitudinal axis 40, while being directed towards, incident and impinging upon, and milling, a surface of the work piece. In a range of between 0 degrees and 360 degrees per rotation.

First time derivative of the rotational angle or angular displacement of the ion beam: d(rotational angle or angular displacement of the ion beam)/dt, where t represents time. Rate of change of the rotational angle or angular displacement of rotationally directed multi-deflected ion beam 20a, 20b, or 20c, around longitudinal axis 40, while being directed towards, incident and impinging upon, and milling, a surface of the work piece, with time, corresponding to a temporal rate of change of the rotational angle or angular displacement of rotationally directed multi-deflected ion beam 20a, 20b, or 20c, around longitudinal axis 40, while directed towards, incident and impinging upon, and milling, a surface of the work piece.

Second time derivative of the rotational angle or angular displacement of the ion beam: d.sup.2(rotational angle or angular displacement of the ion beam)/dt.sup.2, where t represents time. Rate of change of the first time derivative of the rotational angle or angular displacement of rotationally directed multi-deflected ion beam 20a, 20b, or 20c, around longitudinal axis 40, while being directed towards, incident and impinging upon, and milling, a surface of the work piece, with time, corresponding to a temporal rate of change of the first time derivative of the rotational angle or angular displacement of rotationally directed multi-deflected ion beam 20a, 20b, or 20c, around longitudinal axis 40, while directed towards, incident and impinging upon, and milling, a surface of the work piece.

Direction, path, or trajectory, of the ion beam: the direction, path, or trajectory, of directed multi-deflected ion beam 20a, 20b, or 20c, corresponding to above illustratively described specific linear or (conical or conical-like, or cylindrical) rotational spatial (directional, orientational, configurational) modes or manners of multi-deflecting and directing provided ion beam 10, relative to longitudinal axis 40, while directed multi-deflected ion beam 20a, 20b, or 20c, is directed towards, incident and impinging upon, and milling, a surface of the work piece.

Another main aspect of the present invention is a sub-combination of the method for directed multi-deflected ion beam milling of a work piece, as described hereinabove, whereby there is provision of a method for directed multi-deflecting a provided ion beam, including the following main steps, and, components and functionalities thereof: directing and at least twice deflecting the provided ion beam, for forming a directed multi-deflected ion beam, by deflecting and directing the provided ion beam, for forming a directed once deflected ion beam, and, deflecting and directing the directed once deflected ion beam, for forming a directed twice deflected ion beam being a type of the multi-deflected ion beam.

Accordingly, with reference to FIG. 2, along with additional reference to FIGS. 3, 4, 5, 8, 9, and 10, the method for directed multi-deflecting a provided ion beam, includes: directing and at least twice deflecting the provided ion beam 10, for forming a directed multi-deflected ion beam 20a, 20b, or 20c, by deflecting and directing the provided ion beam 10, for forming a directed once deflected ion beam (for example, shown in FIGS. 3 and 8 as 16a or 16b; and in FIGS. 4, 5, 9, and 10, as 16), and, deflecting and directing the directed once deflected ion beam (16a or 16b, or 16, respectively), for forming a directed twice deflected ion beam being a type of the directed multi-deflected ion beam 20a, 20b, or 20c.

Another main aspect of the present invention is provision of a device for directed multi-deflected ion beam milling of a work piece, including the following main components and functionalities thereof: an ion beam source assembly, for providing an ion beam; and an ion beam directing and multi-deflecting assembly, for directing and at least twice deflecting the provided ion beam, for forming a directed multi-deflected ion beam, wherein the directed multi-deflected ion beam is directed towards, incident and impinges upon, and mills, a surface of the work piece.

FIG. 3 is a schematic diagram illustrating a side view of a more detailed version of the exemplary preferred embodiment illustrated in FIG. 2, particularly showing an exemplary specific preferred embodiment of the device, being ion beam unit 100, including ion beam directing and multi-deflecting assembly 120, for twice deflecting an ion beam 10, and showing an exemplary specific preferred embodiment of the work piece imaging and milling detection unit 300.

FIG. 4 is a schematic diagram illustrating a side view of the directed multi-deflected ion beam milling of a work piece, and, determining and controlling extent thereof, illustrated in FIGS. 2 and 3, particularly showing a cross-sectional side view of a more detailed component level version of the device, being ion beam unit 100, including ion beam directing and multi-deflecting assembly 120, structured and functional for twice deflecting an ion beam 10.

The above illustrative description of the different exemplary specific preferred embodiments of the method for directed multi-deflected ion beam milling of a work piece, according to the specific linear or rotational spatial (directional, orientational, configurational) modes or manners, and according to the specific continuous or discontinuous temporal (timing) modes or manners, of multi-deflecting and directing provided ion beam 10, wherein directed multi-deflected ion beam 20a, 20b, or 20c, is directed towards, incident and impinges upon, and mills, a surface of the work piece, as shown in FIG. 2, is generally applicable for illustratively describing the device, being ion beam unit 100, shown in FIGS. 3 and 4, wherein ion beam unit 100 includes ion beam directing and multi-deflecting assembly 120, specifically for twice deflecting provided ion beam 10.

Accordingly, as shown in FIGS. 2, 3, and 4, the device, being ion beam unit 100, for directed multi-deflected ion beam milling of a work piece, includes the following main components and functionalities thereof: an ion beam source assembly 110, for providing an ion beam 10; and an ion beam directing and multi-deflecting assembly 120, for directing and at least twice deflecting provided ion beam 10, for forming directed multi-deflected ion beam 20a or 20b (in FIGS. 2 and 3; and in FIG. 4, generally indicated as 20) wherein directed multi-deflected ion beam 20a or 20b (in FIGS. 2 and 3; 20 in FIG. 4) is directed towards, incident and impinges upon, and mills, a surface of the work piece.

As stated, ion beam source assembly 110 is for providing an ion beam 10. In general, ion beam source assembly 110 generates ion beam 10 by ionizing a non-ionized particle supply, for example, which is supplied to ion beam source assembly 110, for example, by a non-ionized particle supply assembly 112. In general, non-ionized particle supply assembly 112 is either separate from, or integral to, ion beam source assembly 110. Preferably, non-ionized particle supply assembly 112 is separate from, and operatively connected to, ion beam source assembly 110, for example, as shown in FIGS. 3 and 4.

In general, the non-ionized particle supply is essentially any type and phase of chemical which is capable of being ionized, such that in an ionized form is capable of milling the work piece. Preferably, the non-ionized particle supply is selected from the group consisting of a gas, and a liquid metal. An exemplary gas type of non-ionized particle supply is an inert gas, such as argon, or xenon. An exemplary liquid metal type of non-ionized particle supply is liquid gallium.

The device, that is, ion beam unit 100, of the present invention, is used for performing a broad ion beam (BIB) type of milling of the work piece, or, alternatively, for performing a focused ion beam (FIB) type of milling of the work piece. Accordingly, for a broad ion beam (BIB) type of implementation of the device, that is, ion beam unit 100, of the present invention, the non-ionized particle supply is an inert gas, such as argon, or xenon. Alternatively, for a focused ion beam (FIB) milling type of implementation of the device, that is, ion beam unit 100, of the present invention, the non-ionized particle supply is a liquid metal type of non-ionized particle supply, in particular, liquid gallium. Preferably, non-ionized particle supply 112 is an inert gas, such as argon, or xenon, for preventing or minimizing generation of artifacts on or within the surface of the work piece, thereby, improving the quality of the milled surface, during the ion beam milling of the work piece.

In general, in ion beam unit 100, ion beam source assembly 110 can be of various different types. For example, ion beam source assembly 110 is a duoplasmatron (BIB) type of ion beam source assembly, or alternatively, is an electron impact (BIB) type of ion beam source assembly, wherein each, non-ionized particle supply 112 is an inert gas, such as argon, or xenon.

FIG. 5 is a schematic diagram illustrating a perspective view of the directed multi-deflected ion beam milling of a work piece, illustrated in FIGS. 2, 3, and 4, particularly showing an exemplary specific preferred embodiment of each of the ion beam first deflecting assembly 122 and the ion beam second deflecting assembly 124, included in ion beam directing and multi-deflecting assembly 120 of ion beam unit 100, structured and functional for twice deflecting an ion beam 10.

With reference to FIGS. 2, 3, 4, and 5, ion beam directing and multi-deflecting assembly 120 is for directing and at least twice deflecting provided ion beam 10, for forming directed multi-deflected ion beam 20a or 20b (in FIGS. 2 and 3; 20 in FIGS. 4 and 5), wherein directed multi-deflected ion beam 20a or 20b (in FIGS. 2 and 3; 20 in FIGS. 4 and 5) is directed towards, incident and impinges upon, and mills, a surface of the work piece.

Ion beam directing and multi-deflecting assembly 120 includes the following main components and functionalities thereof: an ion beam first deflecting assembly 122, for deflecting and directing provided ion beam 10, for forming a directed once deflected ion beam 16a or 16b (in FIG. 3; 16 in FIGS. 4 and 5) and an ion beam second deflecting assembly 124, for deflecting and directing directed once deflected ion beam 16a or 16b (in FIG. 3; 16 in FIGS. 4 and 5), for forming a directed twice deflected ion beam 20a or 20b (in FIGS. 2 and 3; 20 in FIGS. 4 and 5), respectively, being a type of directed multi-deflected ion beam 20a or 20b (in FIGS. 2 and 3; 20 in FIGS. 4 and 5), respectively.

In general, ion beam first deflecting assembly 122 includes a set of two pairs of, preferably, symmetrically positioned electrostatic plates or electrodes, wherein each pair, the electrostatic plates or electrodes are separated by a pre-determined separation distance. 10 For example, with reference to FIGS. 4 and 5, ion beam first deflecting assembly 122 includes a set of two pairs, of, preferably, symmetrically positioned electrostatic plates or electrodes, that is, a first pair of symmetrically positioned electrostatic plates or electrodes 122a, and a second pair of symmetrically positioned electrostatic plates or electrodes 122b, wherein each pair, the electrostatic plates or electrodes are separated by a separation distance.

In ion beam first deflecting assembly 122, each pair of electrostatic plates or electrodes, that is, first pair of electrostatic plates or electrodes 122a, and second pair of electrostatic plates or electrodes 122b, is supplied with a voltage provided by a designated operatively connected power supply, for example, P.sub.1 and P.sub.2, respectively, as particularly shown in FIG. 4. During operation of ion beam first deflecting assembly 122, the magnitude of the voltage supplied to first pair of electrostatic plates or electrodes 122a by power supply P.sub.1, and to second pair of electrostatic plates or electrodes 122b by power supply P.sub.2, determines the extent of spatial (linear and rotational) deflection of provided ion beam 10, in general, and preferably, a directed focused ion beam 14, relative to longitudinal axis 40, for forming directed once deflected ion beam 16a or 16b (in FIG. 3; 16 in FIGS. 4 and 5).

An important objective of operating ion beam first deflecting assembly 122, is to optimally spatially (linearly or/and rotationally) and temporally (continuously or/and discontinuously) deflect and direct provided ion beam 10, in general, and, preferably, directed focused ion beam 14, into the inter-electrode space of ion beam second deflecting assembly 124.

With reference to FIG. 4, ion beam first deflecting assembly 122 deflects provided ion beam. 10, in general, and preferably, directed focused ion beam 14, relative to longitudinal axis 40, according to a deflection angle, or an angle of deflection, herein, referred to as .theta.sub.D. This is particularly shown in FIG. 4, where directed focused ion beam 14 enters, is deflected according to a deflection angle, .theta.sub.D, and exits, ion beam first deflecting assembly 122 in the form of a directed once deflected ion beam 16.

In general, ion beam second deflecting assembly 124 includes a set of two (an inner and an outer) symmetrically and concentrically positioned and spherically or elliptically shaped or configured electrostatic plates or electrodes, wherein the electrostatic plates or electrodes are uniformly (i.e., circumferentially) separated by a pre-determined separation distance. For example, with reference to FIGS. 4 and 5, ion beam second deflecting assembly 124 includes a set of two symmetrically and concentrically positioned and spherically or elliptically shaped or configured electrostatic plates or electrodes, that is, a inner symmetrically positioned and spherically or elliptically shaped or configured electrostatic plate or electrodes 124a, and an outer symmetrically positioned and spherically or elliptically shaped or configured electrostatic plate or electrode 124b, wherein the electrostatic plates or electrodes are separated by a separation distance.

In ion beam second deflecting assembly 124, each electrostatic plate or electrode, that is, inner electrostatic plate or electrode 124a, and outer electrostatic plate or electrode 124b, is supplied with a voltage provided by a designated operatively connected power supply, for example, P.sub.3 and P.sub.4, respectively, as particularly shown in FIG. 4. During operation of ion beam second deflecting assembly 124, the magnitude of the voltage supplied to inner electrostatic plate or electrode 124a by power supply P.sub.3, and to outer electrostatic plate or electrode 124b by power supply P.sub.4, determines the extent of spatial (linear and rotational) deflection of directed once deflected ion beam 16a or 16b (in FIG. 3; 16 in FIGS. 4 and 5), relative to longitudinal axis 40, for forming directed twice deflected ion beam 20a or 20b (in FIGS. 2 and 3; 20 in FIGS. 4 and 5), respectively, being a type of directed multi-deflected ion beam 20a or 20b (in FIGS. 2 and 3; 20 in FIGS. 4 and 5), respectively.

An important objective of operating ion beam second deflecting assembly 124, is to optimally spatially (linearly or/and rotationally) and temporally (continuously or/and discontinuously) deflect and direct directed once deflected ion beam 16a or 16b (in FIG. 3; 16 in FIGS. 4 and 5), in the form of directed twice deflected ion beam 20a or 20b (in FIGS. 2 and 3; 20 in FIGS. 4 and 5), respectively, being multi-deflected ion beam 20a or 20b, respectively, such that directed twice deflected ion beam 20a or 20b, being directed multi-deflected ion beam 20a or 20b, is directed towards, incident and impinges upon, and mills, a surface of the work piece.

With reference to FIG. 4, ion beam second deflecting assembly 124 deflects directed once deflected ion beam 16, relative to longitudinal axis 40, according to an incidence angle, or an angle of incidence, herein, referred to as .theta.sub.I, upon a surface of the work piece, wherein directed twice deflected ion beam 20a or 20b, being directed multi-deflected ion beam 20a or 20b, respectively, is directed towards, incident and impinges upon, and mills, the surface of the work piece. The maximum incidence angle or angle of incidence, .theta.sub.I, of directed twice deflected ion beam 20a or 20b, being directed multi-deflected ion beam 20a or 20b, respectively, relative to longitudinal axis 40 and upon a surface of the work piece is, preferably, in a range of between about 0 degrees and about 90 degrees, and more preferably, between about 0 degrees and about 30 degrees.

As shown in FIG. 4, .alpha.sub.D: (90-.theta.sub.D) corresponds to the half-angle at the apex of inner electrostatic plate or electrode 124a of ion beam second deflecting assembly 124, while a,: (90-.theta.sub.1) corresponds to the half-angle at the apex of second electrostatic plate or electrode 124b of ion beam second deflecting assembly 124, which faces the work piece.

With reference to FIGS. 3 and 4, in ion beam unit 100, ion beam directing and multi-deflecting assembly 120, preferably, further includes an ion beam focusing assembly 126, for focusing and directing provided ion beam 10, for forming a directed focused ion beam 14. With reference to FIG. 4, ion beam focusing assembly 126 includes the main components: a first electrostatic lens 132, a second electrostatic lens 134, and an aperture 136.

First electrostatic lens 132 is for preliminary focusing of ion beam 10 provided by ion beam source assembly 110. First electrostatic lens 132 is supplied with a voltage provided by a designated operatively connected power supply, for example, P.sub.5, as particularly shown in FIG. 4.

Second electrostatic lens 134 is for further focusing, and directing, of ion beam 10 provided by ion beam source assembly 110, to the inter-electrode space between first pair of electrostatic plates or electrodes 122a and second pair of electrostatic plates or electrodes 122b of ion beam first deflecting assembly 122. Second electrostatic lens 134 is supplied with a voltage provided by a designated operatively connected power supply, for example, P.sub.6, as particularly shown in FIG. 4.

Aperture 136 is for limiting or restricting the diameter of ion beam 10 provided by ion beam source assembly 110.

With reference to FIGS. 3 and 4, in ion beam directing and multi-deflecting assembly 120 of ion beam unit 100, ion beam focusing assembly 126, optionally, and preferably, is operatively connected to, or further includes an ion beam deflecting sub-assembly 128, for deflecting provided ion beam 10 in the direction of, and along longitudinal axis 40 [i.e., the x-axis (in z=0 domain)], such that provided ion beam 10 is maintained coaxial with longitudinal axis 40 to a high degree of accuracy.

With reference to FIGS. 3 and 4, in ion beam unit 100, ion beam directing and multi-deflecting assembly 120, preferably, further includes an ion beam extractor assembly 130, for extracting and directing ion beam 10 provided by ion beam source assembly 110, for forming a directed extracted ion beam 12.

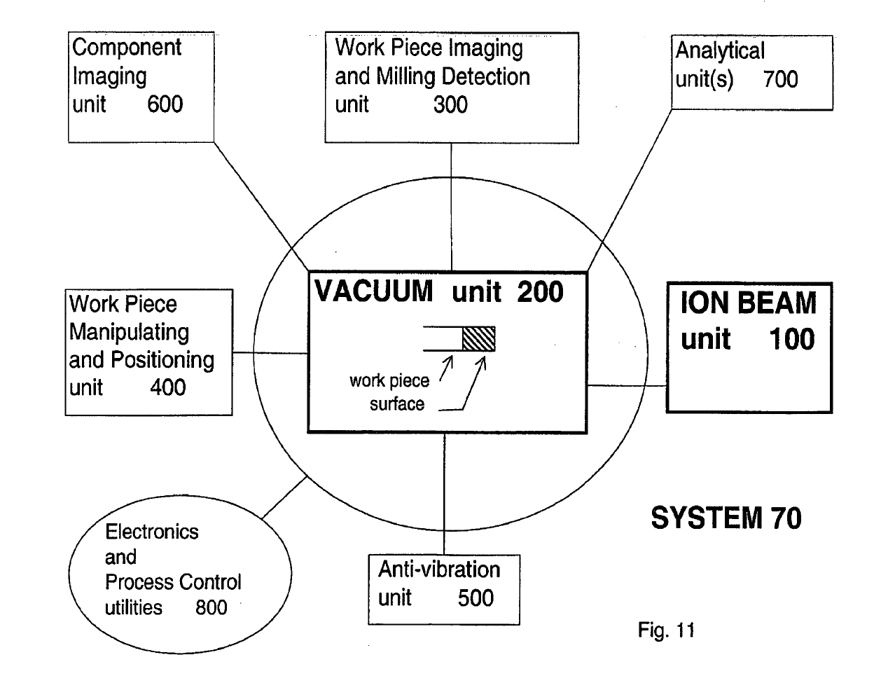

With reference to FIGS. 3 and 4, in ion beam unit 100, ion beam directing and multi-deflecting assembly 120, preferably, further includes an ion beam vacuum chamber assembly 150, for housing the various assemblies, sub-assemblies, components, and elements, of ion beam directing and multi-deflecting assembly 120, and for allowing maintenance of a vacuum environment of ion beam unit 100 when operatively connected to vacuum chamber assembly 210 of a vacuum unit, in particular, vacuum unit 200 of system 70, as further described hereinbelow, with reference to FIGS. 11, 12, and 13.

FIG. 5 is a schematic diagram illustrating a perspective view of the directed multi-deflected ion beam milling of a work piece, illustrated in FIGS. 2, 3, and 4, particularly showing an exemplary specific preferred embodiment of each of the ion beam first deflecting assembly 122 and the ion beam second deflecting assembly 124, included in ion beam directing and multi-deflecting assembly 120 of ion beam unit 100, structured and functional for twice deflecting an ion beam 10.

FIGS. 6a-6e are schematic diagrams together illustrating a perspective view of a rotational (angular) sequence of an ion beam directed and multi-deflected, relative to arbitrarily assigned longitudinal axis 40 coaxial with the work piece, by first ion beam deflecting assembly 122 and second ion beam deflecting assembly 124a and 124b, corresponding to a directed twice deflected ion beam type of directed multi-deflected ion beam 20 which rotates in a range of between 0 degrees and 360 degrees around longitudinal axis 40, and is directed towards, incident and impinges upon, and mills, a surface of the work piece.

FIG. 7a is a schematic diagram illustrating a perspective close-up view of a directed multi-deflected ion beam 20 (twice deflected) or 22 (thrice deflected) directed towards, incident and impinging upon, and milling, a surface of a first type of an exemplary work piece (a generally shaped rectangular slab), particularly showing relative geometries and dimensions of ion beam 20 or 22, the surface, and the work piece. FIG. 7b is a schematic diagram illustrating a perspective close-up view of a directed multi-deflected ion beam 20 (twice deflected) or 22 (thrice deflected) directed towards, incident and impinging upon, and milling, a surface of a second type of an exemplary work piece (a typical sample of a portion of a semiconductor wafer or chip wherein the surface (with a mask) is held by a sample holder element, for example, similar to that illustrated in FIG. 1), particularly showing relative geometries and dimensions of ion beam 20 or 22, the surface, and the work piece. The diameter, d, of the directed multi-deflected ion beam 20 (twice deflected) or 22 (thrice deflected), is preferably, in a range of between about 30 microns and about 2000 microns (2 millimeters), and more preferably, in a range of between about 200 microns and about 1000 microns (1 millimeter).

FIG. 8 is a schematic diagram illustrating a side view of a more detailed version of the exemplary preferred embodiment illustrated in FIG. 2, particularly showing an exemplary specific preferred embodiment of the ion beam unit 100, including the ion beam directing and multi-deflecting assembly 120, for thrice deflecting an ion beam 10, and an exemplary specific preferred embodiment of the work piece imaging and milling detection unit 300.

The above illustrative description of the different exemplary specific preferred embodiments of the method for directed multi-deflected ion beam milling of a work piece, according to the specific linear or rotational spatial (directional, orientational, configurational) modes or manners, and according to the specific continuous or discontinuous temporal (timing) modes or manners, of multi-deflecting and directing provided ion beam 10, wherein directed multi-deflected ion beam 20a, 20b, or 20c, is directed towards, incident and impinges upon, and mills, a surface of the work piece, as shown in FIG. 2, is generally applicable for illustratively describing the device, being ion beam unit 100, shown in FIG. 8, wherein ion beam unit 100 includes ion beam directing and multi-deflecting assembly 120, specifically for thrice deflecting provided ion beam 10.

FIG. 9 is a schematic diagram illustrating a side view of the directed multi-deflected ion beam milling of a work piece, and, determining and controlling extent thereof, illustrated in FIGS. 2 and 8, particularly showing a cross-sectional side view of a more detailed component level version of the ion beam unit 100, including the ion beam directing and multi-deflecting assembly 120, structured and functional for twice deflecting an ion beam 10.

FIG. 10 is a schematic diagram illustrating a perspective view of the directed multi-deflected ion beam milling of a work piece, illustrated in FIGS. 2, 8, and 9, particularly showing an exemplary specific preferred embodiment of each of the ion beam first deflecting assembly 122, the ion beam second deflecting assembly 124, and the ion beam third deflecting assembly 140, included in the ion beam directing and multi-deflecting assembly 120 of the ion beam unit 100, structured and functional for thrice deflecting an ion beam.

Another main aspect of the present invention is a sub-combination of the device for directed multi-deflected ion beam milling of a work piece, whereby there is provision of a device for directed multi-deflecting a provided ion beam, including the following main components and functionalities thereof: an ion beam directing and multi-deflecting assembly, for directing and at least twice deflecting the provided ion beam, for forming a directed multi-deflected ion beam, wherein the ion beam directing and multi-deflecting assembly includes an ion beam first deflecting assembly, for deflecting and directing the provided ion beam, for forming a directed once deflected ion beam, and an ion beam second deflecting assembly, for deflecting and directing the directed once deflected ion beam, for forming a directed twice deflected ion beam being a type of the multi-deflected ion beam.

Another main aspect of the present invention is provision of a system for directed multi-deflected ion beam milling of a work piece, including the following main components: an ion beam unit, wherein the ion beam unit includes an ion beam source assembly, for providing an ion beam, and an ion beam directing and multi-deflecting assembly, for directing and at least twice deflecting the provided ion beam, for forming a directed multi-deflected ion beam, wherein the directed multi-deflected ion beam is directed towards, incident and impinges upon, and mills, a surface of the work piece; and a vacuum unit, operatively connected to the ion beam unit, for providing and maintaining a vacuum environment for the ion beam unit and the work piece.

Preferably, the vacuum unit includes the work piece. More specifically, preferably, the work piece is included inside the vacuum chamber assembly of the vacuum unit, in a stationary (static or fixed) configuration, or in a movable configuration, as well as in a removable configuration, relative to the directed multi-deflected ion beam, and relative to the vacuum chamber assembly of the vacuum unit, for example, by operative connection of the work piece to a work piece manipulating and positioning unit.

Preferably, the system further includes electronics and process control utilities, operatively connected to the ion beam unit and to the vacuum unit, for providing electronics to, and enabling process control of, the ion beam unit and the vacuum unit. Optionally, and preferably, the system further includes at least one additional unit selected from the group consisting of: a work piece imaging and milling detection unit, a work piece manipulating and positioning unit, an anti-vibration unit, a component imaging unit, and a work piece analytical unit, wherein each additional unit is operatively connected to the vacuum unit. Preferably, the electronics and process control utilities is also operatively connected to each additional unit, for providing electronics to, and enabling process control of, each additional unit, in a manner operatively integrated with the ion beam unit and the vacuum unit.

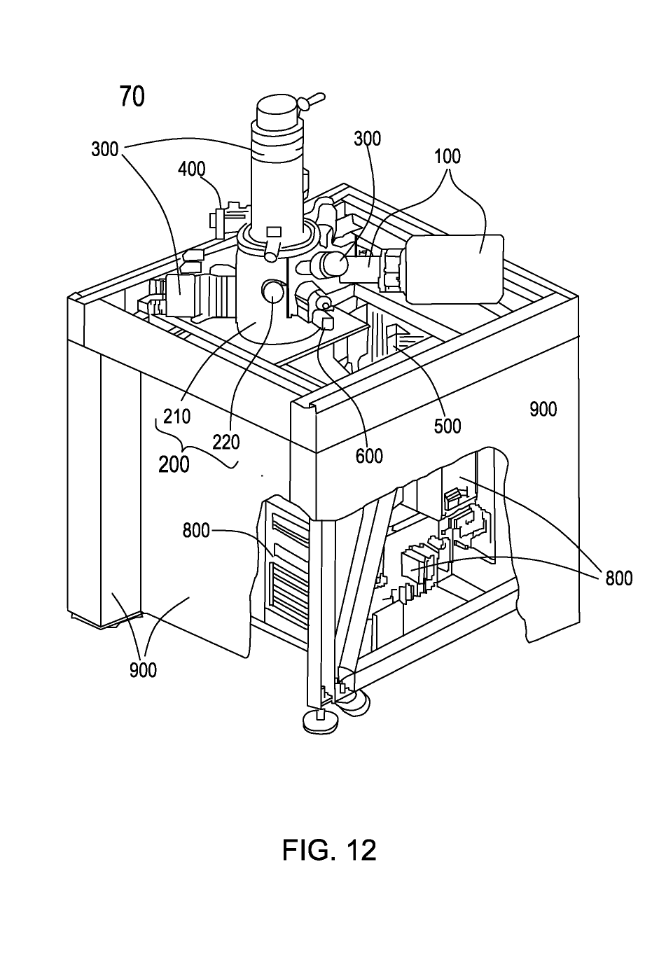

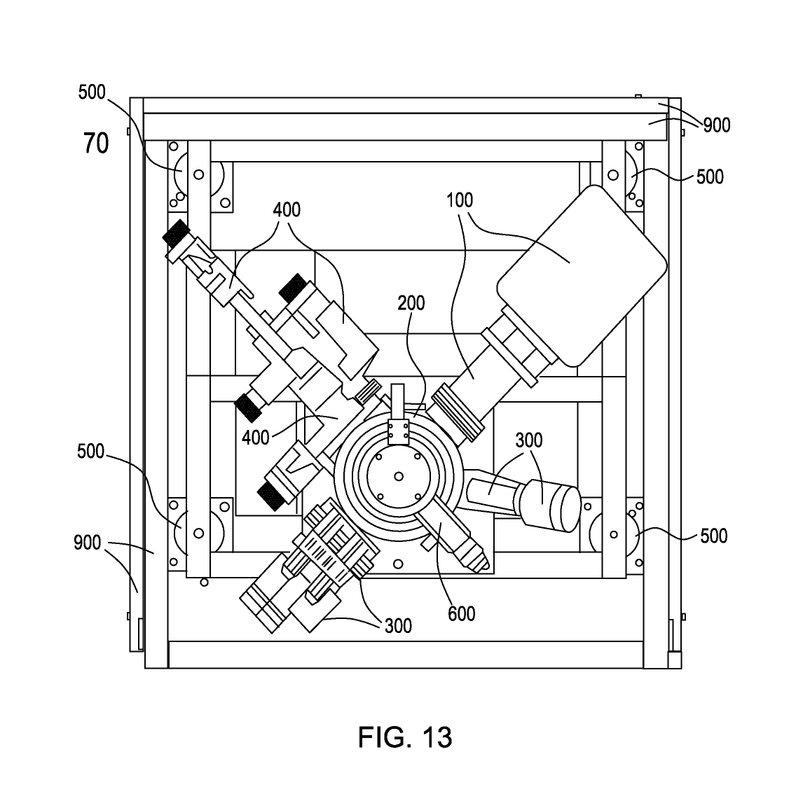

FIG. 11 is a block diagram illustrating an exemplary preferred embodiment of the system, herein, generally referred to as system 70, for directed multi-deflected ion beam milling of a work piece, including the main components: ion beam unit 100, as previously illustratively described hereinabove, and a vacuum unit 200. Preferably, vacuum unit 200 includes the work piece. FIG. 12 is an (isometric) schematic diagram illustrating a perspective view of system 70, and additional units thereof, for directed multi-deflected ion beam milling of a work piece, illustrated in FIG. 11. FIG. 13 is an (isometric) schematic diagram illustrating a top view of system 70 illustrated in FIGS. 11 and 12.

In system 70 shown in FIGS. 11, 12, and 13, ion beam unit 100, as previously illustratively described hereinabove, with reference to FIGS. 2-10, includes ion beam source assembly 110, for providing ion beam 10, and ion beam directing and multi-deflecting assembly 120, for directing and at least twice deflecting provided ion beam 10, for forming a directed multi-deflected ion beam 20, wherein directed multi-deflected ion beam 20 is directed towards, incident and impinges upon, and mills, a surface of the work piece. Vacuum unit 200 is operatively connected to ion beam unit 100 for providing and maintaining a vacuum environment for ion beam unit 100 and the work piece. Preferably, as shown in FIGS. 11, 12, and 13, system 70 further includes electronics and process control utilities 800, operatively connected (for example, in FIG. 11, indicated by the larger ellipse intersecting operative connection of ion beam unit 100 and vacuum unit 200) to ion beam unit 100 and to vacuum unit 200, for providing electronics to, and enabling process control of, ion beam unit 100 and vacuum unit 200.

Optionally, and preferably, system 70 further includes at least one additional unit selected from the group consisting of: a work piece imaging and milling detection unit 300, a work piece manipulating and positioning unit 400, an anti-vibration unit 500, a component imaging unit 600, and at least one work piece analytical unit 700, wherein each additional unit is operatively connected to vacuum unit 200. Preferably, electronics and process control utilities 800 is also operatively connected to each additional unit, for providing electronics to, and enabling process control of, each additional unit, in a manner operatively integrated with ion beam unit 100 and vacuum unit 200.

Accordingly, the present invention provides various alternative specific exemplary preferred embodiments of the system, that is, system 70, for directed multi-deflected ion beam milling of a work piece.

In a non-limiting manner, as shown in FIGS. 12 and 13, several units or components thereof, of system 70 are directly mounted onto, and operatively connected to, a fixed or mobile table, stand, or frame, type of system support assembly 900, including appropriately constructed support elements, legs, brackets, and mobile elements, such as wheels, whereas other system units or components thereof are mounted onto those system units or components thereof which are directly mounted onto system support assembly 900.

As stated, with reference to FIGS. 11, 12, and 13, in system 70, vacuum unit 200, preferably including the work piece, is operatively connected to ion beam unit 100 for providing and maintaining a vacuum environment for ion beam unit 100 and the work piece. Vacuum unit 200 also functions as an overall structure or housing of ion beam unit 100 and of the work piece, as well as of optional additional units of system 70.

With respect to functionality and operation of vacuum unit 200, vacuum unit 200 includes the following main components: a vacuum chamber assembly 210, a work piece inserting/removing assembly 220, a vacuum gauge assembly, a pre-pump assembly, a high vacuum pump assembly, and a vacuum distribution assembly.

Vacuum chamber assembly 210, as particularly shown in FIGS. 2, 3, 4, 8, and 9, in relation to ion beam unit 100 and work piece imaging and milling detection unit 300, and in FIG. 12, in relation to various system units, functions as the structure which provides the vacuum environment for ion beam unit 100, and components thereof, and the various possible optional additional units, and components thereof, of system 70. Vacuum chamber assembly 210 also functions as an overall structure or housing of ion beam unit 100, and components thereof, and the various possible optional additional units, and components thereof, of system 70. For example, preferably, the work piece is included inside vacuum chamber 210 assembly of vacuum unit 200, in a stationary (static or fixed) configuration, or in a movable configuration, as well as in a removable configuration, relative to directed multi-deflected ion beam 20, and relative to vacuum chamber assembly 210 of vacuum unit 200, for example, by operative connection of the work piece to work piece manipulating and positioning unit 400.

Vacuum chamber assembly 210 is the location of the overall vacuum environment of system 70. Vacuum chamber assembly 210 is operatively connected to ion beam unit 100, and to each optional additional unit of system 70, for example, work piece imaging and milling detection unit 300, work piece manipulating and positioning unit 400, anti-vibration unit 500, component imaging unit 600, and at least one work piece analytical unit 700. Vacuum chamber assembly 210 houses work piece inserting/removing assembly 220, and the vacuum gauge assembly. The other assemblies, that is, vacuum gauge assembly, pre-pump assembly, high vacuum pump assembly, and vacuum distribution assembly, of vacuum unit 200, are located at various different positions throughout system 70, and are operatively connected to vacuum chamber assembly 210.

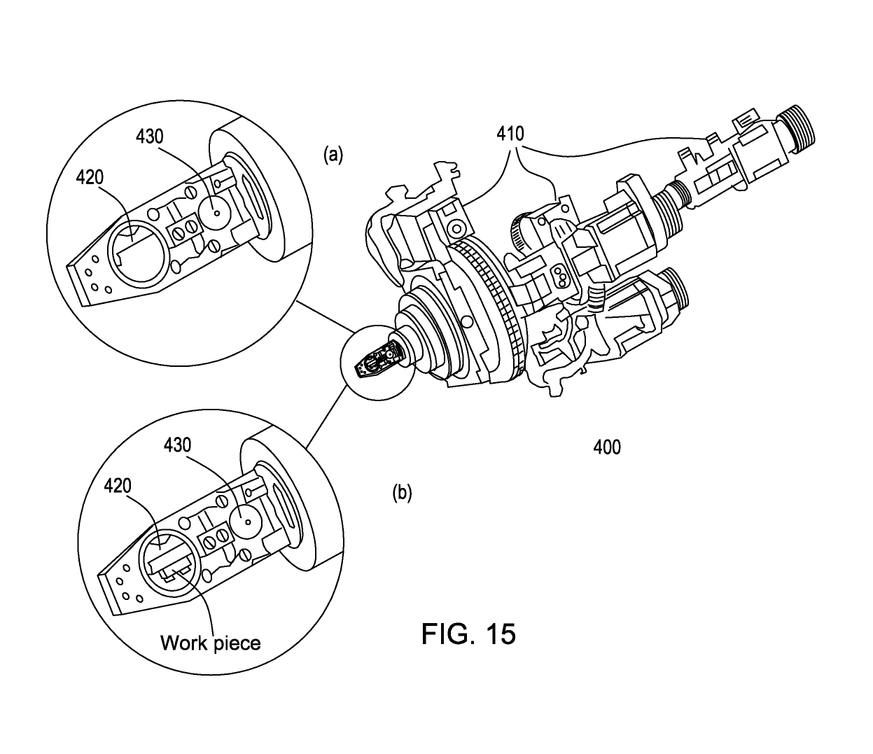

Work piece inserting/removing assembly 220 (for example, partly shown in FIG. 12) functions for enabling inserting of the work piece into vacuum chamber assembly 210, and enabling removing of the work piece from vacuum chamber assembly 210, for example, via work piece manipulating and positioning unit 400 (FIG. 15). A first specific exemplary embodiment of work piece inserting/removing assembly 220 is in the form of a sealed shutter or shutter-like element, which operates during the time of inserting the work piece into vacuum chamber assembly 210, or removing the work piece from vacuum chamber assembly 210. A second specific exemplary embodiment of work piece inserting/removing assembly 220 is in the form of an air lock.

For an exemplary preferred embodiment of system 70 which includes work piece manipulating and positioning unit 400, then, work piece inserting/removing assembly 220, for example, in the form of an air lock, functions for preserving the vacuum environment existing throughout vacuum chamber assembly 210 of vacuum unit 200, at the time of inserting the work piece into vacuum chamber assembly 210, or removing the work piece from vacuum chamber assembly 210, via work piece manipulating and positioning unit 400. Such a work piece inserting/removing assembly 220 typically includes as main components: a chamber, and a connecting valve.

With reference to FIG. 15, in such an embodiment, the chamber functions as the region or volume of space within which takes place loading the work piece onto a work piece holder assembly 420, or unloading the work piece from work piece holder assembly 420. The internal environment of the chamber is either at atmospheric pressure, or at vacuum, depending upon the actual stage of loading of the work piece onto work piece holder assembly 420, or of unloading of the work piece from work piece holder assembly 420. For an exemplary preferred embodiment of system 70 which includes work piece manipulating and positioning unit 400, then, for example, 5-axis/6 DOF (degree-of-freedom) work piece manipulating and positioning assembly 410 of work piece manipulating and positioning unit 400 is used for transferring of work piece holder assembly 420 between the chamber of the air lock assembly and vacuum chamber assembly 210 of vacuum unit 200.

Further, in such an embodiment, the connecting valve functions for joining the region or volume of space of the chamber of the air lock assembly to the region or volume of space of vacuum chamber assembly 210, as well as for separating the region or volume of space of the chamber of the air lock assembly from the region or volume of space of vacuum chamber assembly 210. In general, the connecting valve is essentially any type of valve which functions and is structured for enabling manual, semi-automatic, or fully automatic, joining of a region or volume of space of a first chamber to a region or volume of space of a second chamber, as well as for separating the region or volume of space of the first chamber from the region or volume of space of the second chamber. Preferably, the connecting valve functions and is structured for enabling fully automatic operation during the joining or separating of the regions or volumes of spaces of the chamber of the air lock assembly and vacuum chamber assembly 210. Such an automatic connecting valve is either a pneumatic or electrical type of valve. Alternatively, the connecting valve functions and is structured for enabling manual operation during the joining or separating of the regions or volumes of spaces of the chamber of the air lock assembly and vacuum chamber assembly 210. An exemplary type of manual connecting valve is a type of valve which is opened or closed via a manual handle.

For an exemplary preferred embodiment of system 70 which does not include sample manipulating and positioning unit 400, then work piece inserting/removing assembly 220 in the form of an air lock, preferably, further includes a work piece holder receiver.

The vacuum gauge assembly functions for continuously gauging or monitoring the vacuum state existing within vacuum chamber assembly 210, and the vacuum state existing within the chamber of the air lock assembly, at any time before, during, or after, loading of the work piece onto work piece holder assembly 420, or unloading of the work piece from work piece holder assembly 420, via work piece manipulating and positioning unit 400. The vacuum gauge assembly includes as main components: at least one vacuum gauge operatively connected to vacuum chamber assembly 210, and at least one vacuum gauge operatively connected to the chamber of the air lock assembly.

In vacuum unit 200, the pre-pump assembly, and the high vacuum pump assembly are for pumping vacuum chamber assembly 210 down to about 10.sup.-3 Torr, and down to about 10. sup.-6 Torr, respectively. Vacuum unit 200 optionally includes assemblies and related equipment for providing and maintaining ultra-high vacuum conditions, for example, with a vacuum environment having a pressure as low as about 10.sup.-10 Torr, in vacuum chamber assembly 210, and in optional additional units of system 70.

The vacuum distribution assembly is for distributing and maintaining different pre-determined levels of vacuum to different units of system 70, which are operatively connected to vacuum chamber assembly 210 of vacuum unit 200, and for purging the different units of system 70 of positive pressure. For example, purging the air lock assembly of vacuum unit 200 at any time before, during, or after, loading of the work piece onto work piece holder assembly 420, or unloading of the work piece from work piece holder assembly 420, via work piece manipulating and positioning unit 400.

With reference to FIGS. 11, 12, 13, and 14, system 70, optionally, and preferably, includes work piece imaging and milling detection unit 300, for imaging the work piece, and determining and controlling the extent of ion beam milling of the work piece. Preferably, work piece imaging and milling detection unit 300 is operatively connected to vacuum chamber assembly 210 of vacuum unit 200.

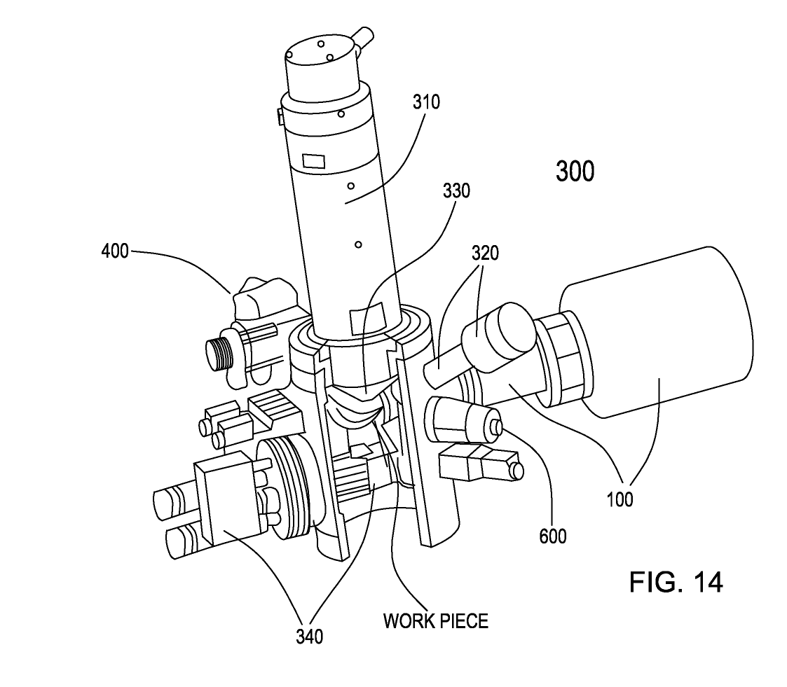

FIG. 14 is an (isometric) schematic diagram illustrating a perspective view of an exemplary specific preferred embodiment of the work piece imaging and milling detection unit 300, and main components thereof, in relation to the ion beam unit 100, the work piece manipulating and positioning unit 400, the component imaging unit 600, and all these in relation to the work piece, as part of system 70 illustrated in FIGS. 12 and 13.

With reference to FIG. 14, work piece imaging and milling detection unit 300 includes the main components of: a scanning electron microscope (SEM) column assembly 310, a secondary electron detector assembly 320, a back-scattered electron detector assembly 330, and a transmission electron detector assembly 340. Work piece imaging and milling detection unit 300, and selected main components thereof, are shown in FIGS. 2, 3, 4, 8, 9, 16, and 17, in operative relation to the various system units, and assemblies thereof, illustrated therein.

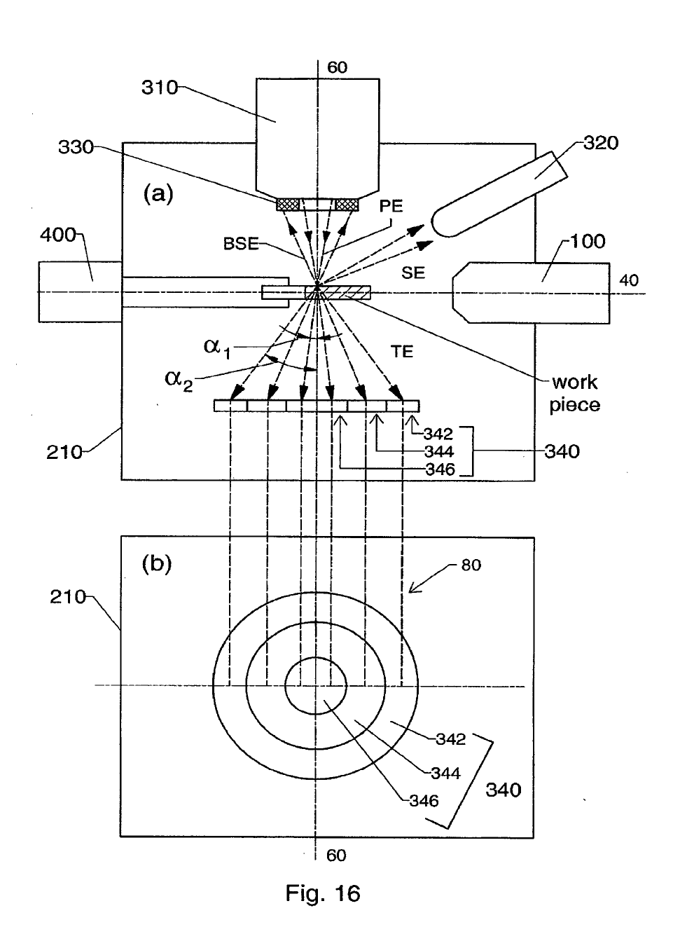

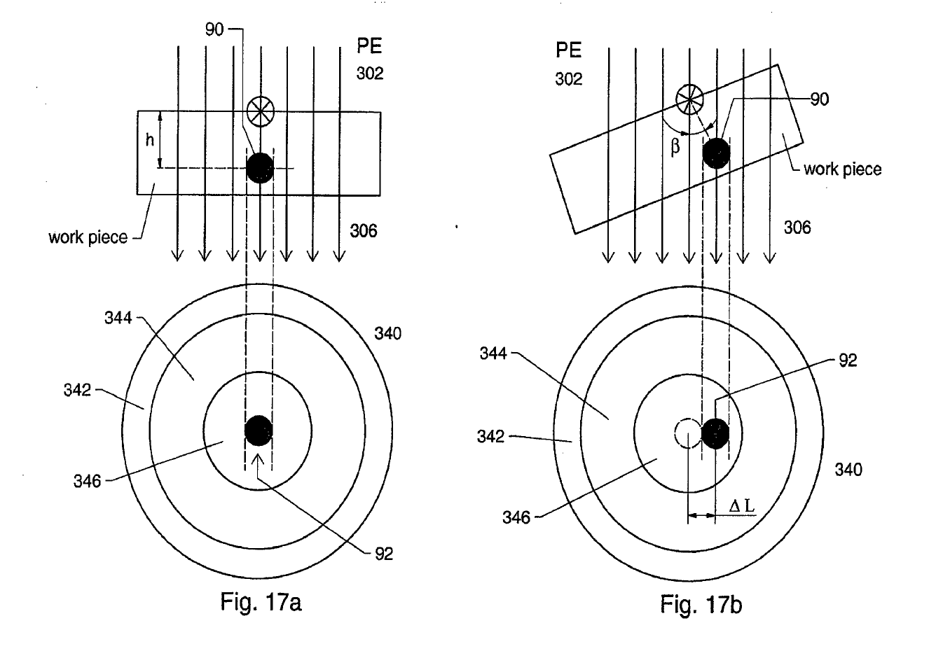

SEM column assembly 310 is for generating an electron beam probe of primary electrons, herein, referenced by 302 (in FIGS. 2, 3, 4, 8, 9, 17a, and 17b), and by PE (in FIGS. 16, 17a, and 17b), which scan along a surface of the work piece.

In system 70, wherein optionally, and preferably, there is included work piece imaging and milling detection unit 300, then SEM column assembly 310 included therein, together with secondary electron detector assembly 320, or/and back-scattered electron detector assembly 330, can also function for physically analyzing the surface of the work piece. Alternatively, or additionally, SEM column assembly 310 can operate in STEM mode by utilizing transmitted electron detector assembly 340 of work piece imaging and milling detection unit 300, for the work piece being transparent to electrons, for physically analyzing the bulk material of the work piece.

Secondary electron detector assembly 320 is for detecting secondary electrons, herein, referenced by 318 (FIGS. 3 and 8), and by SE (FIG. 16), which are emitted from a surface of the work piece, as a result of interaction between primary electrons 302 (FIGS. 2, 3, 4, 8, 9, 17a, and 17b), and PE (FIGS. 16, 17a, and 17b), and the surface of the work piece. A signal of detected secondary electrons 318 is processed for obtaining images of the surface of the work piece. Preferably, secondary electron detector assembly 320 is continuously operative during implementation of the present invention.

Back-scattered electron detector assembly 330 is for detecting primary electrons 302 (FIGS. 2, 3, 4, 8, 9, 17a, and 17b), and PE (FIGS. 16, 17a, and 17b), which are back-scattered from the sub-surface or/and surface layers of the work piece. A signal of the detected back-scattered primary electrons 308 (FIGS. 3 and 8) is processed for obtaining images of the surface of the work piece. Preferably, back-scattered electron detector assembly 330 is continuously operative during implementation of the present invention.

Transmission electron detector assembly 340 is for detecting primary electrons 302 (FIGS. 2, 3, 4, 8, 9, 17a, and 17b), and PE (FIGS. 16, 17a, and 17b), which are transmitted through the work piece. Preferably, transmission electron detector assembly 340 is continuously operative during implementation of the present invention.

For brevity, in FIG. 2, secondary electrons and back-scattered electrons, herein, collectively referred to by 304, are generally shown being detected by work piece imaging and milling detection unit 300.

With reference to FIGS. 11, 12, 13, and 15, system 70, optionally, and preferably, includes work piece manipulating and positioning unit 400, for manipulating the work piece. Work piece manipulating and positioning unit 400 is operatively connected to vacuum chamber assembly 210 of vacuum unit 200.

FIG. 15 is an (isometric) schematic diagram illustrating a perspective view of an exemplary specific preferred embodiment of the work piece manipulating and positioning unit 400, and main components thereof, particularly showing close-up views of the work piece holder assembly 420 without a work piece (a), and with a work piece (b), as part of system 70 illustrated in FIGS. 11, 12, and 13. As shown in FIG. 15, work piece manipulating and positioning unit 400, includes the main components of: a 5-axis/6 DOF (degrees of freedom) work piece manipulator assembly 410, a work piece holder assembly 420, and a calibrating assembly 430.

5-axis/6 DOF (degrees of freedom) work piece manipulator assembly 410 is for manipulating and positioning the work piece relative to the directed multi-deflected ion beam 20, and relative to vacuum chamber assembly 210 of vacuum unit 200.

Work piece holder assembly 420 is for facilitating inserting of the work piece into vacuum chamber assembly 210, and facilitating removing of the work piece from vacuum chamber assembly 210, of vacuum unit 200. Work piece holder assembly 420 additionally functions for holding the work piece during the directed multi-deflected ion beam milling of the work piece.

Calibrating assembly 430 is for enabling calibration of the work piece with respect to directed multi-deflected ion beam 20 of ion beam unit 100, and with respect to the beam of primary electrons transmitted by SEM column assembly 310 of work piece imaging and milling detection unit 300.

For an exemplary preferred embodiment of system 70 which includes work piece manipulating and positioning unit 400, then, for example, 5-axis/6 DOF (degree-of-freedom) work piece manipulating and positioning assembly 410 of work piece manipulating and positioning unit 400 is used for transferring of work piece holder assembly 420 between the chamber of the air lock assembly and vacuum chamber assembly 210 of vacuum unit 200. 5 With reference to FIGS. 11, 12, and 13, system 70, optionally, and preferably, includes anti-vibration unit 500, for preventing or minimizing occurrence of vibrations during operation of system 70. Anti-vibration unit 500, and components thereof, are directly mounted onto, and operatively connected to, system support assembly 900. Anti-vibration unit 500 includes the main components of a plurality of electro-pneumatic or/and electromechanical active damping assemblies, for example, four electro-pneumatic active damping assemblies, generally indicated by 500 in FIG. 13. Preferably, electronics and process control utilities 800 is operatively connected to anti-vibration unit 500, for providing electronics to, and enabling process control of anti-vibration unit 500.

With reference to FIGS. 11, 12, 13, and 14, system 70, optionally, and preferably, includes component imaging unit 600, for imaging the work piece, as well as components of selected optional and preferred additional units, in particular, work piece imaging and milling detection unit 300, work piece manipulating and positioning unit 400, and at least one work piece analytical unit 700. Component imaging unit 600 is also used for imaging directed multi-deflected ion beam 20 exiting ion beam directing and multi-deflecting assembly 120 and being directed towards, incident and impinging upon, and milling, a surface of the work piece, as particularly shown in FIG. 14.

Component imaging unit 600 is operatively connected to vacuum chamber assembly 210. Component imaging unit 600 has as main component a video camera, generally indicated by 600 in FIGS. 12, 13, and 14. Preferably, electronics and process control utilities 800 is operatively connected to component imaging unit 600, for providing electronics to, and enabling process control of component imaging unit 600.

With reference to FIG. 11, system 70, optionally, and preferably, includes at least one work piece analytical unit 700, for analyzing the work piece. In general, system 70, including ion beam unit 100 and vacuum unit 200, and at least one work piece analytical unit 700, is particularly implementable for analyzing a wide variety of different types of work pieces, particularly in the form of samples or materials, such as those derived from semiconductor wafers or chips, that are widely used in the above indicated exemplary fields.

Ordinarily, each work piece analytical unit 700 is at least partly operatively connected to vacuum chamber assembly 210 of vacuum unit 200. Preferably, electronics and process control utilities 800 is operatively connected to each work piece analytical unit 700, for providing electronics to, and enabling process control of, each work piece analytical unit 700.

Work piece analytical unit 700 is, for example, a SIMS (secondary ion mass spectrometer) using directed multi-deflected ion beam 20, of ion beam unit 100, which is incident and impinges upon (without necessarily milling) a surface of the work piece. For such an exemplary specific embodiment of system 70, vacuum unit 200 preferably includes assemblies and related equipment for providing and maintaining ultra-high vacuum conditions, for example, with a vacuum environment having a pressure as low as about 10.sup.-10 Torr, in vacuum chamber assembly 210. which include components of the SIMS. Alternatively, work piece analytical unit 700 is an EDS (energy dispersion spectrometer) using a beam of primary electrons PE generated by SEM column assembly 310 of work piece imaging and milling detection unit 300.

In system 70, wherein optionally, and preferably, there is included work piece imaging and milling detection unit 300, then SEM column assembly 310 included therein, can also function for physically analyzing the surface of the work piece. Alternatively, or additionally, SEM column assembly 310 can operate in STEM mode by utilizing transmitted electron detector assembly 340 of work piece imaging and milling detection unit 300, for the work piece being transparent to electrons, for physically analyzing the bulk material of the work piece.

In system 70, electronics and process control utilities 800, in addition to providing electronics to, and enabling process control of, ion beam unit 100 and vacuum unit 200, is for providing electronics to, and enabling process control of, the optional additional operatively connected system units.

Electronics and process control utilities 800, in addition to being operatively connected to ion beam unit 100 and to vacuum unit 200, is operatively connected to each optional additional unit, that is, work piece imaging and milling detection unit 300, work piece manipulating and positioning unit 400, anti-vibration unit 500, component imaging unit 600, or/and at least one work piece analytical unit 700, of system 70.

Electronics and process control utilities 800 has any number of the following main components: a central control panel or board, at least one computer, microprocessor, or central processing unit (CPU), along with associated computer software, power supplies, power converters, controllers, controller boards, various printed circuit boards (PCBs), for example, including input/output (I/O) and D/A (digital to analog) and A/D (analog to digital) functionalities, cables, wires, connectors, shieldings, groundings, various electronic interfaces, and network connectors.

With reference to FIGS. 4 and 9, electronics and process control utilities 800 is operatively connected and integrated with the various power supplies of ion beam unit 100, in general, and in particular, the power supplies of ion beam source assembly 110, and ion beam directing and multi-deflecting assembly 120.

Another main aspect of the present invention is a sub-combination of the system for directed multi-deflected ion beam milling of a work piece, whereby there is provision of a system for directed multi-deflecting a provided ion beam, including the following main components and functionalities thereof: an ion beam unit, wherein the ion beam unit includes an ion beam directing and multi-deflecting assembly, for directing and at least twice deflecting the provided ion beam, for forming a directed multi-deflected ion beam, the ion beam directing and multi-deflecting assembly includes an ion beam first deflecting assembly, for deflecting and directing the provided ion beam, for forming a directed once deflected ion beam, and an ion beam second deflecting assembly, for deflecting and directing the directed once deflected ion beam, for forming a directed twice deflected ion beam being a type of the multi-deflected ion beam; and a vacuum unit, operatively connected to the ion beam unit, for providing and maintaining a vacuum environment for the ion beam unit.

Accordingly, with reference to FIGS. 2-14, the system for directed multi-deflecting a provided ion beam includes the following main components and functionalities thereof: an ion beam unit 100, as illustratively described hereinabove, wherein ion beam unit 100 includes an ion beam directing and multi-deflecting assembly 120, for directing and at least twice deflecting the provided ion beam 10, for forming a directed multi-deflected ion beam 20, the ion beam directing and multi-deflecting assembly 120 includes an ion beam first deflecting assembly 122, for deflecting and directing the provided ion beam 10, for forming a directed once deflected ion beam 16, and an ion beam second deflecting assembly 124, for deflecting and directing the directed once deflected ion beam 16, for forming a directed twice deflected ion beam 20 being a type of the multi-deflected ion beam; and a vacuum unit 200, operatively connected to the ion beam unit 100, for providing and maintaining a vacuum environment for the ion beam unit 100.

Another main aspect of the present invention is provision of a method for determining and controlling extent of ion beam milling of a work piece, including the following main steps, and, components and functionalities thereof: providing a set of pre-determined values of at least one parameter of the work piece selected from the group consisting of: thickness of the work piece, depth of a target within the work piece, and topography of at least one surface of the work piece; performing directed multi-deflected ion beam milling of the work piece using a method for the directed multi-deflected ion beam milling of a work piece, including the following main steps, and, components and functionalities thereof: providing an ion beam; and directing and at least twice deflecting the provided ion beam, for forming a directed multi-deflected ion beam, wherein the directed multi-deflected ion beam is directed towards, incident and impinges upon, and mills, a surface of the work piece; real time measuring in-situ the at least one parameter of the work piece, for forming a set of measured values of the at least one parameter; comparing the set of the measured values to the provided set of the pre-determined values, for forming a set of value differences associated with the comparing; feeding back the set of the value differences for continuing the performing directed multi-deflected ion beam milling of the work piece, until the value differences are within a pre-determined range.

In the method for determining and controlling extent of ion beam milling of a work piece, the degree of selectivity of the at least one surface of the work piece corresponds to the topography as being one of the pre-determined parameters of the work piece.

The method for determining and controlling extent of ion beam milling of a work piece, is according to a closed-loop feedback control of the three parameters: thickness of the work piece, depth of a target 90 within the work piece, and topography of at least one surface of the work piece. There are known methods for measuring (determining) the thickness, however, the present method provides the ability to perform real-time, in-situ control of these parameters, and to do so in an automated manner, whereby ion beam milling of the work piece is controlled to end at a pre-determined thickness, with target 90 positioned at a pre-determined depth, and to have the bordering surfaces (top and bottom) have a controlled topography, either with or without selectivity, including extent of the selectivity, and for these surfaces to be either (preferably) parallel, or without a pre-determined offset angle in reference to the longitudinal axis 40.

This control is enabled by the method of static work piece, directed multi-deflected ion beam milling, and real-time, in-situ SEM/STEM imaging (with best resolution), including use of SE, BSE and TE detectors, either in combination, or separately. In another exemplary specific preferred embodiment, this control is enabled by involving the work piece manipulating and positioning unit 400 to change the position of the work piece, either by rotating the work piece in relation to the longitudinal axis 40 by 180 degrees, in order to allow either of top or bottom surfaces of the work piece to be imaged by the electron beam of the SEM. An exemplary method for controlling the depth of a target 90 in the work piece is to tilt the work piece by means of the work piece manipulating and positioning unit 400 and to register the corresponding shift, .DELTA.L, of target 90 as imaged by the transmitted electron detector 340 of the work piece imaging and milling detection unit 300, in comparison to the non-tilted image 92 of target 90. The depth of target 90 within the work piece is calculated from the angle of tilt, herein, referred to as A, and the degree or extent of shift of the image 92 of target 90, as shown in FIGS. 16, 17a, and 17b.

FIG. 16 is a schematic diagram illustrating a combined cross-section view (upper part (a)) and top view (lower part (b)) of using the exemplary specific preferred embodiment of the work piece imaging and milling detection unit 300, and main components thereof, along with the ion beam unit 100, and the work piece manipulating and positioning unit 400, as part of system 70 illustrated in FIGS. 11, 12, and 13, in relation to the work piece, illustrated in FIG. 14, for determining and controlling extent of ion beam milling of a work piece. In FIG. 16, 80 refers to the projection of the detector segments, that is, 342, 344, and 346, of transmitted electron detector assembly 340, wherein each detector segment operates as an independent detector, each operatively connected to an separate electronic circuit, part of electronics and process control utilities 800 of system 70. The signals from detector segments, that is, 342, 344, and 346, of transmitted electron detector assembly 340, can be used for measuring or imaging, according to any desired combination, in particular, as relating to bright field and dark field STEM images.

FIGS. 17a and 17b are schematic diagrams illustrating a cross-section view of determining depth of a target 90 within a milled work piece, as part of determining and controlling extent of ion beam milling of a work piece, using the transmitted electron detector assembly included in the work piece imaging and milling detection unit illustrated in FIGS. 14 and 16.

Based upon the above indicated aspects of novelty and inventiveness, and, beneficial and advantageous aspects, characteristics, or features, the present invention successfully overcomes limitations, and widens the scope, of presently known techniques of ion beam milling.

It is appreciated that certain aspects and characteristics of the invention, which are, for clarity, described in the context of separate embodiments, may also be provided in combination in a single embodiment. Conversely, various aspects and characteristics of the invention, which are, for brevity, described in the context of a single embodiment, may also be provided separately or in any suitable sub-combination.

All publications, patents and patent applications mentioned in this specification are herein incorporated in their entirety by reference into the specification, to the same extent as if each individual publication, patent or patent application was specifically and individually indicated to be incorporated herein by reference. In addition, citation or identification of any reference in this application shall not be construed as an admission that such reference is available as prior art to the present invention.

While the invention has been described in conjunction with specific embodiments and examples thereof, it is evident that many alternatives, modifications and variations will be apparent to those skilled in the art. Accordingly, it is intended to embrace all such alternatives, modifications and variations that fall within the spirit and broad scope of the appended claims.

We claim:

1. A method for directing and multiple times deflecting an ion beam for milling of a work piece, comprising:
providing an ion beam; and
directing and at least twice deflecting said provided ion beam, for forming a directed multi-deflected ion beam, by deflecting and directing said provided ion beam by an ion beam first deflecting assembly, for forming a directed once deflected ion beam, and, deflecting and directing said directed once deflected ion beam by an ion beam second deflecting assembly, for forming a directed twice deflected ion beam being a type of said directed multi-deflected ion beam, wherein said directed multi-deflected ion beam is directed towards, incident and impinges upon, and mills, a surface of the work piece;
wherein said ion beam second deflecting assembly includes an inner and an outer symmetrically and concentrically positioned, separated, spherically or elliptically shaped electrostatic plates or electrodes for said deflecting and directing said directed once deflected ion beam;
wherein the work piece is in a stationary configuration relative to said directed multi-deflected ion beam, and in that type of the ion beam milling is broad ion beam (BIB) milling, such that said directed multi-deflected ion beam is a directed multi-deflected broad ion beam, wherein said directed multi-deflected broad ion beam has a diameter or width in a range of between about 30 microns and about 2000 microns (2 millimeters).

2. The method of claim 1, wherein said directing and at least twice deflecting said provided ion beam includes extracting and directing said provided ion beam, for forming a directed extracted ion beam.

3. The method of claim 1, wherein said directing and at least twice deflecting said provided ion beam includes deflecting and directing said directed twice deflected ion beam, for forming a directed thrice deflected ion beam being another said type of said directed multi-deflected broad ion beam.

4. The method of claim 1, wherein said directed multi-deflected ion beam is rotationally directed, and is converted into, and becomes, a rotationally directed multi-deflected ion beam which extends conically or conically-like towards, and projects as a circle or ellipse upon, the work piece.

5. The method of claim 4, wherein said conically or conically-like rotationally directed multi-deflected ion beam is according to a clockwise or counterclockwise direction.

6. The method of claim 5, wherein said clockwise or counterclockwise direction is according to a partial rotation greater than 0 degrees and less than 360 degrees, or according to at least one complete rotation equal to or greater than 360 degrees.

7. The method of claim 6, wherein said partial or complete rotation is according to a back-and-forth rocking or oscillatory type of conical or conical-like rotational motion.

8. The method of claim 1, wherein said directed multi-deflected ion beam is rotationally directed, and is converted into, and becomes, a rotationally directed multi-deflected ion beam which extends cylindrically towards, and projects as a circle upon, the work piece.

9. The method of claim 8, wherein said cylindrically rotationally directed multi-deflected ion beam is according to a clockwise or counterclockwise direction.

10. The method of claim 9, wherein said clockwise or counterclockwise direction is according to a partial rotation greater than 0 degrees and less than 360 degrees, or according to at least one complete rotation equal to or greater than 360 degrees.

11. The method of claim 10, wherein said partial or complete rotation is according to a back-and-forth rocking or oscillatory type of cylindrical rotational motion.

12. A method for determining and controlling extent of ion beam milling of a work piece, comprising:
providing a set of pre-determined values of at least one parameter of the work piece; selected from the group consisting of: thickness of the work piece, depth of a target within the work piece, and topography of at least one surface of the work piece; directing and multiple times deflecting an ion beam for performing the ion beam
milling of the work piece using a method comprising:
providing an ion beam; and
directing and at least twice deflecting said provided ion beam, for forming a directed multi-deflected ion beam, by deflecting and directing said provided ion beam by an ion beam first deflecting assembly, for forming a directed once deflected ion beam, and, deflecting and directing said directed once deflected ion beam by an ion beam second deflecting assembly, for forming a directed twice deflected ion beam being a type of said directed multi-deflected ion beam, wherein the directed multi-deflected ion beam is directed towards, incident and impinges upon, and mills, a surface of the work piece;
real time measuring in-situ said at least one parameter of the work piece, for forming a set of measured values of said at least one parameter;
comparing said set of said measured values to said provided set of said pre-determined values, for forming a set of value differences associated with said comparing;
feeding back said set of said value differences for continuing said directing and multiple times deflecting of said ion beam for the ion beam milling of the work piece, until said value differences are within a pre-determined range;
wherein the directing and multiple time deflecting of said ion beam for performing the ion beam milling, said ion beam second deflecting assembly includes an inner and an outer symmetrically and concentrically positioned, separated, spherically or elliptically shaped electrostatic plates or electrodes for said deflecting and directing said directed once deflected ion beam.

13. The method of claim 12, wherein degree of selectivity of said at least one surface of the work piece corresponds to said topography of the work piece.

14. The method of claim 13, further comprising real-time, in-situ SEM or STEM imaging or measuring of the work piece.

15. The method of claim 12, wherein said parameter of the work piece is said thickness of the work piece, and wherein said real time measuring includes use of a transmitted electron detector.

16. The method of claim 12, wherein said feeding back is performed according to a closed-loop feedback control.

17. The method of claim 12, wherein said surface has a controlled topography with or without selectivity.

18. The method of claim 12, wherein the work piece is in a stationary (static or fixed) configuration relative to said directed multi-deflected ion beam.

19. The method of claim 12, wherein type of the ion beam milling is broad ion beam (BIB) milling, such that said directed multi-deflected ion beam is a directed multi-deflected broad ion beam.

20. The method of claim 19, wherein said directed multi-deflected broad ion beam has a diameter or width in a range of between about 30 microns and about 2000 microns (2 millimeters).

21. The method of claim 12, wherein type of the ion beam milling is focused ion beam (FIB) milling, such that said directed multi-deflected ion beam is a directed multi-deflected focused ion beam.

22. The method of claim 21, wherein said directed multi-deflected focused ion beam has a diameter or width in a range of between about 5 nanometers and about 100 nanometers.

23. The method of claim 12, wherein said directed multi-deflected ion beam is rotationally directed, and is converted into, and becomes, a rotationally directed multi-deflected ion beam which extends conically or conically-like towards, and projects as a circle or ellipse upon, the work piece.

24. The method of claim 23, wherein said conically or conically-like rotationally directed multi-deflected ion beam is according to a clockwise or counterclockwise direction.

25. The method of claim 24, wherein said clockwise or counterclockwise direction is according to a partial rotation greater than 0 degrees and less than 360 degrees, or according to at least one complete rotation equal to or greater than 360 degrees.

26. The method of claim 25, wherein said partial or complete rotation is according to a back-and-forth rocking or oscillatory type of conical or conical-like rotational motion.

27. The method of claim 12, wherein said directed multi-deflected ion beam is rotationally directed, and is converted into, and becomes, a rotationally directed multi-deflected ion beam which extends cylindrically towards, and projects as a circle upon, the work piece.

28. The method of claim 27, wherein said cylindrically rotationally directed multi-deflected ion beam is according to a clockwise or counterclockwise direction.

29. The method of claim 28, wherein said clockwise or counterclockwise direction is according to a partial rotation greater than 0 degrees and less than 360 degrees, or according to at least one complete rotation equal to or greater than 360 degrees.

30. The method of claim 29, wherein said partial or complete rotation is according to a back-and-forth rocking or oscillatory type of cylindrical rotational motion.

31. A system suitable for directing and multiple times deflecting an ion beam for milling of a work piece, the system comprising:
an ion beam unit, wherein said ion beam unit includes an ion beam source assembly, for providing an ion beam, and an ion beam directing and multi-deflecting assembly, for directing and at least twice deflecting said provided ion beam, for forming a directed multi-deflected ion beam, wherein said directed multi-deflected ion beam is directed towards, incident and impinges upon, and mills, a surface of the work piece, wherein said ion beam directing and multi-deflecting assembly includes an ion beam first deflecting assembly, for deflecting and directing said provided ion beam, for forming a directed once deflected ion beam, and an ion beam second deflecting assembly, for deflecting and directing said directed once deflected ion beam, for forming a directed twice deflected ion beam being a type of said directed multi-deflected ion beam; and
a vacuum unit, operatively connected to said ion beam unit, for providing and maintaining a vacuum environment for said ion beam unit and the work piece, wherein said vacuum unit includes the work piece;
wherein said ion beam unit, said ion beam second deflecting assembly includes an inner and an outer symmetrically and concentrically positioned, separated, spherically or elliptically shaped electrostatic plates or electrodes for said deflecting and directing said directed once deflected ion beam;
wherein the work piece is in a stationary configuration relative to said directed multi-deflected ion beam, and in that type of the ion beam milling is broad ion beam (BIB) milling, such that said directed multi-deflected ion beam is a directed multi-deflected broad ion beam, wherein said directed multi-deflected broad ion beam has a diameter or width in a range of between about 30 microns and about 2000 microns (2 millimeters).

32. The system of claim 31, wherein said ion beam directing and multi-deflecting assembly includes an ion beam extractor assembly, for extracting and directing said provided ion beam, for forming a directed extracted ion beam.

33. The system of claim 31, wherein said ion beam directing and multi-deflecting assembly includes an ion beam third deflecting assembly, for deflecting and directing said directed twice deflected ion beam, for forming a directed thrice deflected ion beam being another said type of said directed multi-deflected broad ion beam.

34. The system of claim 31, further comprising electronics and process control utilities, operatively connected to said ion beam unit and said vacuum unit, for providing electronics and process control to said ion beam unit and said vacuum unit.

35. The system of claim 31, further comprising at least one additional unit selected from the group consisting of: a work piece imaging and milling detection unit, a work piece manipulating and positioning unit, an anti-vibration unit, a component imaging unit, and at least one work piece analytical unit, wherein each said additional unit is operatively connected to said vacuum unit.

36. The system of claim 31, wherein said directed multi-deflected ion beam is rotationally directed, and is converted into, and becomes, a rotationally directed multi-deflected ion beam which extends conically or conically-like towards, and projects as a circle or ellipse upon, the work piece.

37. The system of claim 36, wherein said conically or conically-like rotationally directed multi-deflected ion beam is according to a clockwise or counterclockwise direction.

38. The system of claim 37, wherein said clockwise or counterclockwise direction is according to a partial rotation greater than 0 degrees and less than 360 degrees, or according to at least one complete rotation equal to or greater than 360 degrees.

39. The system of claim 38, wherein said partial or complete rotation is according to a back-and-forth rocking or oscillatory type of conical or conical-like rotational motion.

40. The system of claim 31, wherein said directed multi-deflected ion beam is rotationally directed, and is converted into, and becomes, a rotationally directed multi-deflected ion beam which extends cylindrically towards, and projects as a circle upon, the work piece.

41. The system of claim 40 wherein said cylindrically rotationally directed multi-deflected ion beam is according to a clockwise or counterclockwise direction.

42. The system of claim 41, wherein said clockwise or counterclockwise direction is according to a partial rotation greater than 0 degrees and less than 360 degrees, or according to at least one complete rotation equal to or greater than 360 degrees.

43. The system of claim 42, wherein said partial or complete rotation is according to a back-and-forth rocking or oscillatory type of cylindrical rotational motion.

44. A method for determining and controlling extent of ion beam milling of a work piece, comprising:
providing a set of pre-determined values of at least one parameter of the work piece selected from the group consisting of: thickness of the work piece, depth of a target within the work piece, and topography of at least one surface of the work piece;
directing and multiple times deflecting an ion beam for performing the ion beam milling of the work piece using a method including main steps, and, components and functionalities of:
providing an ion beam; and
directing and at least twice deflecting said provided ion beam, for forming a directed multi-deflected ion beam, by deflecting and directing said provided ion beam by an ion beam first deflecting assembly, for forming a directed once deflected ion beam, and, deflecting and directing said directed once deflected ion beam by an ion beam second deflecting assembly, for forming a directed twice deflected ion beam being a type of said directed multi-deflected ion beam, wherein the directed multi-deflected ion beam is directed towards, incident and impinges upon, and mills, a surface of the work piece;
real time measuring in-situ said at least one parameter of the work piece, for forming a set of measured values of said at least one parameter;
comparing said set of said measured values to said provided set of said pre-determined values, for forming a set of value differences associated with said comparing; and
feeding back said set of said value differences for continuing said directing and multiple times deflecting of said ion beam for the ion beam milling of the work piece, until said value differences are within a pre-determined range.

45. The method of claim 40, wherein degree of selectivity of said at least one surface of the work piece corresponds to said topography of the work piece.

46. The method of claim 40, further comprising real-time, in-situ SEM or/and STEM imaging or/and measuring of the work piece.

47. The method of claim 40, wherein said parameter of the work piece is said thickness of the work piece, and wherein said real time measuring includes use of a transmitted electron detector.

48. The method of claim 40, wherein said feeding back is performed according to a closed-loop feedback control.

49. The method of claim 40, wherein said surface has a controlled topography with or without selectivity.

50. The method of claim 40, wherein the work piece is in a stationary (static or fixed) configuration relative to said directed multi-deflected ion beam.

51. The method of claim 40, wherein type of the ion beam milling is broad ion beam (BIB) milling, such that said directed multi-deflected ion beam is a directed multi-deflected broad ion beam.

52. The method of claim 51, wherein said directed multi-deflected broad ion beam has a diameter or width in a range of between about 30 microns and about 2000 microns (2 millimeters).

53. The method of claim 40, wherein type of the ion beam milling is focused ion beam (FIB) milling, such that said directed multi-deflected ion beam is a directed multi-deflected focused ion beam.

54. The method of claim 53, wherein said directed multi-deflected focused ion beam has a diameter or width in a range of between about 5 nanometers and about 100 nanometers.

55. The method of claim 40, wherein said directed multi-deflected ion beam is rotationally directed, and is converted into, and becomes, a rotationally directed multi-deflected ion beam which extends conically or conically-like towards, and projects as a circle or ellipse upon, the work piece.

56. The method of claim 55, wherein said conically or conically-like rotationally directed multi-deflected ion beam is according to a clockwise or counterclockwise direction.

57. The method of claim 56, wherein said clockwise or counterclockwise direction is according to a partial rotation greater than 0 degrees and less than 400 degrees, or according to at least one complete rotation equal to or greater than 400 degrees.

58. The method of claim 57, wherein said partial or complete rotation is according to a back-and-forth rocking or oscillatory type of conical or conical-like rotational motion.

59. The method of claim 58, wherein said directed multi-deflected ion beam is rotationally directed, and is converted into, and becomes, a rotationally directed multi-deflected ion beam which extends cylindrically towards, and projects as a circle upon, the work piece.

60. The method of claim 59, wherein said cylindrically rotationally directed multi-deflected ion beam is according to a clockwise or counterclockwise direction.

61. The method of claim 60, wherein said clockwise or counterclockwise direction is according to a partial rotation greater than 0 degrees and less than 400 degrees, or according to at least one complete rotation equal to or greater than 400 degrees.

62. The method of claim 61, wherein said partial or complete rotation is according to a back-and-forth rocking or oscillatory type of cylindrical rotational motion.
